(19) United States
(12) Patent Application Publication
(10) Pub. No.: US 2026/0033217 A1
(43) Pub. Date: Jan. 29, 2026

(54) DISPLAY APPARATUS

(71) Applicant: LG Display Co., Ltd., Seoul (KR)

(72) Inventors: Koohan YOU, Paju-si (KR); Haeyong JEONG, Paju-si (KR)

(73) Assignee: LG Display Co., Ltd., Seoul (KR)

(21) Appl. No.: 19/265,698

(22) Filed: Jul. 10, 2025

(30) Foreign Application Priority Data
Jul. 29, 2024 (KR) 10-2024-0100105

(51) Int. Cl. H10K 59/80

(52) U.S. Cl. CPC H10K 59/873

(57) ABSTRACT

A display apparatus according to an embodiment may include a display panel; a main region, a sub-region, and a bending region between the main region and the sub-region; a polarization layer disposed in the main region; a cover layer on the polarization layer; a bonding layer between the polarization layer and the cover layer; and a covering layer disposed in the bending region. The bonding layer has an end that may be farther from the bending region than an end of the polarization layer. The covering layer may be spaced apart from the bonding layer.

### CROSS REFERENCE TO RELATED APPLICATION

The present application claims the benefit of and priority to Korean Patent Application No. 10-2024-0100105, filed Jul. 29, 2024, the entire contents of which are incorporated herein by reference for all purposes.

### TECHNICAL FIELD

This disclosure relates to a display apparatus.

### BACKGROUND

With the advancement of the information society, there is an increasing demand for display devices that can show images, and various types of display devices such as liquid crystal display (LCD) apparatus and organic light emitting diode (OLED) display apparatus are being utilized.

The description of the background should not be considered prior art merely because it is mentioned in or associated with this section. The description of the background includes information that describes one or more aspects of the subject technology, and the description in this section does not limit the scope of the invention.

### SUMMARY

It is an aspect of the embodiments of this disclosure to provide a display apparatus with a narrow bezel.

It is another aspect of the embodiments of this disclosure to provide a display apparatus capable of reducing the generation of bending (waviness) in the bonding layer, which combines the polarization layer and the cover layer, as well as improving external visibility defects.

The aspects of this disclosure are not limited to those mentioned above, and other technical aspects may be inferred from the following embodiments.

A display apparatus according to an embodiment of this disclosure may include a display panel, a main region, a sub-region, a bending region between the main region and the sub-region, a polarization layer disposed in the main region, a cover layer on the polarization layer, a bonding layer between the polarization layer and the cover layer, and a covering layer disposed in the bending region. The bonding layer may have an end that is farther from the bending region than an end of the polarization layer, and the covering layer may be spaced apart from the bonding layer.

A display apparatus according to another embodiment of this disclosure may include a display panel, a main region, a sub-region, a bending region between the main region and the sub-region, a polarization layer disposed in the main region, a cover layer on the polarization layer, a bonding layer between the polarization layer and the cover layer, and a covering layer disposed in the bending region, wherein the bonding layer has an end protruding further toward the bending region compared to an end of the polarization layer. The covering layer may include a first covering layer in contact with the side surface of the polarization layer, and a second covering layer located outside the first covering layer and in contact with the first covering layer. The first covering layer may have a surface height equal to the surface height of the polarization layer.

Additional features, advantages, and aspects of this disclosure are set forth in part in the description that follows and in part will become apparent from this disclosure or may be learned by practice of the inventive concepts provided herein. Other features, advantages, and aspects of this disclosure may be realized and attained by the descriptions provided in this disclosure, or derivable therefrom, and the claims hereof as well as the drawings. It is intended that all such features, advantages, and aspects be included within this description, be within the scope of this disclosure, and be protected by the following claims. Nothing in this section should be taken as a limitation on those claims. Further aspects and advantages are discussed below in conjunction with embodiments of this disclosure.

It is to be understood that both the foregoing description and the following description of this disclosure are examples, and are intended to provide further explanation of this disclosure as claimed.

### BRIEF DESCRIPTION OF THE DRAWINGS

The accompanying drawings, which are included to provide a further understanding of this disclosure, are incorporated in and constitute a part of this disclosure, illustrate aspects and embodiments of this disclosure, and together with the description serve to explain principles and examples of this disclosure. In the drawings:

FIG. 1 is a plan view of a display apparatus according to an embodiment;

FIG. 2 is a cross-sectional view of the display panel of FIG. 1 in a bent state;

FIG. 3 is a plan view of the display panel of FIG. 1 in a bent state;

FIG. 4 is a cross-sectional view taken along line A-A′ of FIG. 3;

FIG. 5 is a detailed cross-sectional view of the lighting-emitting layer of FIG. 4;

FIG. 6 is a detailed cross-sectional view of the light-emitting layer according to an alternative embodiment;

FIG. 7 is a cross-sectional view taken along line B-B′ of FIG. 3;

FIG. 8 is an enlarged cross-sectional view of Q1 area of FIG. 7;

FIG. 9 is a cross-sectional view taken along line C-C′ of FIG. 3;

FIG. 10 is an enlarged cross-sectional view of Q2 area of FIG. 9;

FIG. 11 is a cross-sectional view of a display apparatus according to an embodiment;

FIGS. 12 to 15 are cross-sectional views for explaining the manufacturing method of the display apparatus of FIG. 11;

FIG. 16 is a cross-sectional view of a display apparatus according to another embodiment;

FIG. 17 is a cross-sectional view of a display apparatus according to another embodiment;

FIG. 18 is a cross-sectional view of a display apparatus according to another embodiment;

FIGS. 19 to 20 are cross-sectional views for explaining the manufacturing method of the display apparatus of FIG. 18; and

FIG. 21 is a cross-sectional view of a display apparatus according to another embodiment.

Throughout the drawings and the detailed description, unless otherwise described, the same drawing reference numerals should be understood to refer to the same elements, features, and structures. The sizes, lengths, and thicknesses of layers, regions and elements, and depiction thereof may be exaggerated for clarity, illustration, and/or convenience.

### DETAILED DESCRIPTION

Hereinafter, embodiments will be described with reference to accompanying drawings.

The same reference numerals refer to the same components. Additionally, in the drawings, the thickness, proportions, and dimensions of components may be exaggerated for effective explanation of the technical content. Although depicted in a scale different from their actual scale for the convenience of explanation, the components are not limited to the scale shown in the drawing.

In the disclosure, when a component (or area, layer, part, etc.) is mentioned as being “on top of,” “connected to,” or “coupled to” another component, it means that it may be directly connected/coupled to the other component, or a third component may be placed between them.

The expression “and/or” is taken to include one or more combinations that can be defined by associated components.

The terms “first,” “second,” etc. are used to describe various components, but the components should not be limited by these terms. The terms are used only for distinguishing one component from another component. For example, a first component may be referred to as a second component and, similarly, the second component may be referred to as the first component, without departing from the scope of the present invention. The singular forms are intended to include the plural forms as well unless the context clearly indicates otherwise. For example, an element may be one or more elements. An element may include a plurality of elements. The word “exemplary” is used to mean serving as an example or illustration. Embodiments are example embodiments. Aspects are example aspects. In one or more implementations, “embodiments,” “examples,” “aspects,” and the like should not be construed to be preferred or advantageous over other implementations. An embodiment, an example, an example embodiment, an aspect, or the like may refer to one or more embodiments, one or more examples, one or more example embodiments, one or more aspects, or the like, unless stated otherwise. Further, the term “may” encompasses all the meanings of the term “can.”

The terms such as “below,” “lower,” “above,” “upper,” etc. are used to describe the relationship of components depicted in the drawings. The terms are relative concepts and are described based on the direction indicated on the drawing. For example, unless explicitly stated with terms such as “directly” or “immediately,” one or more other components may be positioned between two described components. Spatially relative terms such as “below,” “beneath,” “lower,” “above,” and “upper” may be used to facilitate the description of the relationship between one component or element and another, as illustrated in the drawings. These spatially relative terms should be understood to include different orientations of a component during use or operation, in addition to the orientation shown in the drawings. For instance, if a component shown in the drawings is flipped, a component described as being “below” or “beneath” another component may then be positioned “above” that component. Accordingly, the term “below,” for example, may encompass both upward and downward directions.

It will be further understood that the terms “comprises,” “has,” and the like are intended to specify the presence of stated features, numbers, steps, operations, components, parts, or a combination thereof but are not intended to preclude the presence or possibility of one or more other features, numbers, steps, operations, components, parts, or combinations thereof.

The various features of the embodiments of the disclosure can combined or assembled together, either partially or entirely, in a technically diverse manner, and each embodiment can be independently implemented or in conjunction with related embodiments.

Hereinafter, the display apparatus according to the embodiments of this disclosure will be described with reference to the accompanying drawings.

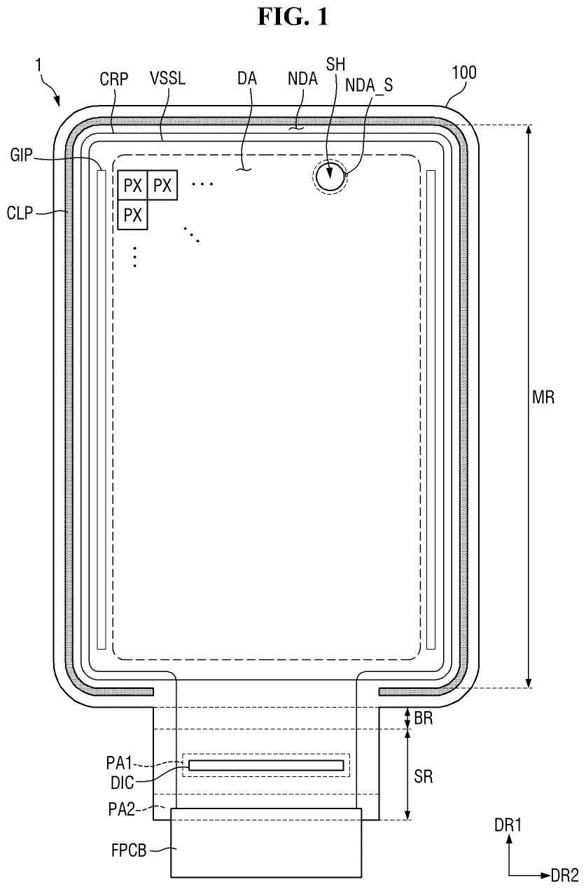

FIG. 1 is a plan view of a display apparatus according to an embodiment.

Referring to FIG. 1, a display apparatus 1 according to an embodiment may include a display panel 100. The display panel 100 may include a display area DA including a plurality of pixels PX and a non-display area NDA surrounding the display area DA. The display area DA may have a rectangular planar shape. However, the display area DA is not limited thereto and may have a square, circular, elliptical, or other polygonal planar shape. For example, the display area DA may have a rounded rectangular shape, but it is not limited thereto and may also be a rectangular shape with sharp corners.

In the embodiments, a first direction DR1 and a second direction DR2 are different directions that intersect each other, such as directions perpendicular to each other in a plan view. In FIG. 1, the first direction DR1 may correspond to the extending direction of the short sides of the display panel 100, while the second direction DR2 may correspond to the extending direction of the long sides of the display panel 100. However, it should be understood that the directions mentioned in the embodiments are relative and are not limited to the specific directions described.

The display area DA may include short sides extending along the first direction DR1 and long sides extending along the second direction DR2. The non-display area NDA may surround the display area DA. The non-display area NDA may be disposed on one side and the other side of the display area DA in the first direction DR1 and on one side and the other side of the display area DA in the second direction DR2.

The display panel 100 may further include a sensor non-display areas NDA_S and a sensor hole SH surrounded by the sensor non-display area NDA_S. The sensor hole SH may be surrounded by the display area DA in a plan view. The sensor hole SH may, for example, be one in number as shown in FIG. 1, but the embodiments of this disclosure are not limited thereto. For example, there are two sensor holes SH, one for an infrared sensor and the other for a camera sensor; however, the embodiments of this disclosure are not limited thereto. The sensor non-display area NDA_S may be disposed between the sensor holes SH and the display area DA. The sensor non-display area NDA_S may completely surround the sensor holes SH. No pixels PX may be arranged in the sensor non-display area NDA_S.

A gate driving unit GIP may be arranged in the non-display area NDA located on each of one side and the other side of the display area DA in the first direction DR1. A low-potential voltage line VSSL may be disposed outside the gate driving unit GIP in the non-display area NDA. For example, as shown in FIG. 1, the low-potential voltage line VSSL may extend from a flexible printed circuit board FPCB, pass through a sub-region SR and a bending region BR, and be positioned outside the gate driving unit GIP in the non-display area NDA while surrounding the display area DA.

The non-display area NDA located on the opposite side of the display area DA in the second direction DR2 may extend further in the second direction DR2 from the central portion of that side of the display area DA. The width in the first direction DR1 of the non-display area NDA, which extends further in the second direction DR2 from the central portion of the opposite side of the display area DA in the second direction DR2, may be smaller than the width in the first direction DR1 of the non-display area NDA adjacent to the non-display area NDA, which extends further in the second direction DR2 from the central portion of the opposite side of the display area DA in the second direction DR2.

The display apparatus 1 may include a main region MR, a sub-region SR, and a bending region BR between the main region MR and the sub-region SR. The display area DA and the non-display area NDA surrounding the display area DA on all four sides may form the main region MR, while the portion extending further in the second direction DR2 from the central portion of the other side of the display area DA may constitute the bending region BR and the sub-region SR. The bending region BR may be positioned between the sub-region SR and the main region MR. The sub-region SR may include a first pad area PA1 and a second pad area PA2 located at the opposite end of the sub-region SR in the second direction DR2.

The display apparatus 1 may further include a data driving unit DIC and a flexible printed circuit board FPCB. The data driving unit DIC may be placed in the first pad area PA1, and the flexible printed circuit board FPCB may be arranged or attached to the second pad area PA2. The first pad area PA1 and the second pad area PA2 may each include a number of pads that connect the data driving unit DIC and the flexible printed circuit board FPCB. The data driving unit DIC may, for example, be provided in the form of a driving chip IC, but is not limited thereto. In an embodiment, the data driving unit DIC is arranged in a chip-on-plastic method, directly mounted on the display panel 100, but is not limited thereto, and may also be arranged in a chip-on-glass or chip-on-film method.

The display panel 100 according to an embodiment may further include a clad portion (CLP). The clad portion CLP may be disposed in the main region MR and may not be disposed in the bending region BR and the sub-region SR. The clad portion CLP may be disposed in the non-display area NDA. The clad portion CLP may be disposed in the non-display areas NDA on one side of the first direction DR1 of the display area DA, the opposite side of the first direction DR1, and one side of the second direction DR2. The clad portions CLP disposed in the non-display areas NDA on the one side of the first direction DR1, the opposite side of the first direction DR1, and one side of the second direction DR2 may be formed integrally; however, the embodiments of this disclosure are not limited thereto. The clad portion CLP may also be partially extended and disposed in the non-display area NDA on the opposite side of the second direction DR2 of the display area DA; however, the embodiments of this disclosure are not limited thereto.

The display panel 100 according to an embodiment may further include a crack detection pattern CRP disposed between the clad portion CLP and the low-potential voltage line VSSL. The crack detection pattern CRP may be arranged to surround or completely enclose the display area DA, as shown in FIG. 1. For example, the crack detection pattern CRP may be placed between the clad portion CLP and the low-potential voltage line VSSL. However, the embodiments of this disclosure are not limited thereto, and the crack detection pattern CRP may not be partially disposed in the non-display area NDA on the opposite side of the display area DA in the second direction DR2.

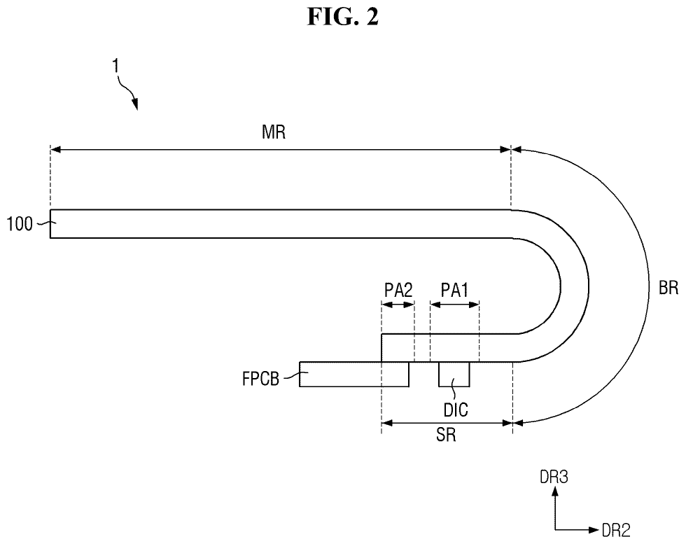

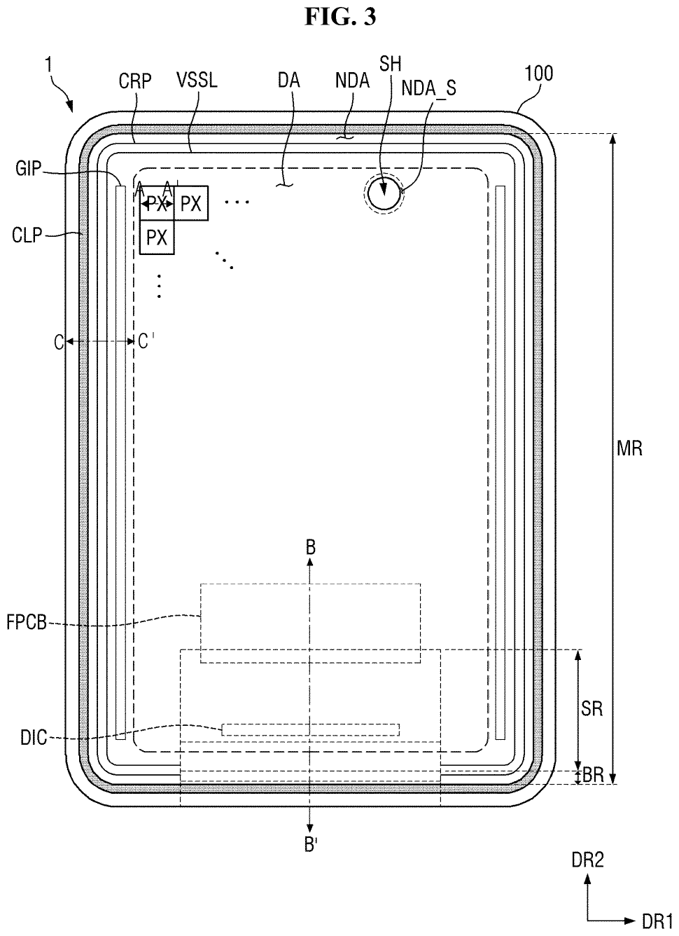

FIG. 2 is a cross-sectional view illustrating a bent state of the display panel in FIG. 1. FIG. 3 is a plan view of the display panel of FIG. 1 in a bent state.

Referring to FIGS. 2 and 3, the bending region BR of the display panel 100 of the display apparatus 1 according to an embodiment may be bent in the thickness direction (or the third direction DR3). Through this, the main region MR and the sub-region SR may overlap in the thickness direction. The display panel 100 may be bent such that the bottom surface of the main region MR and the top surface of the sub-region SR face each other. A flexible printed circuit board FPCB may be disposed or attached to the end of the sub-region SR.

The bending region BR of the display panel 100 may be bent, causing the sub-region SR to overlap with the main region MR. The flexible printed circuit board FPCB and the data driving unit DIC may each overlap with the main region MR; however, the embodiments of this disclosure are not limited thereto.

A housing may further be disposed on the outer side of the display panel 100. The housing may be disposed along the border (or edge) of the display panel 100; however, the embodiments of this disclosure are not limited thereto.

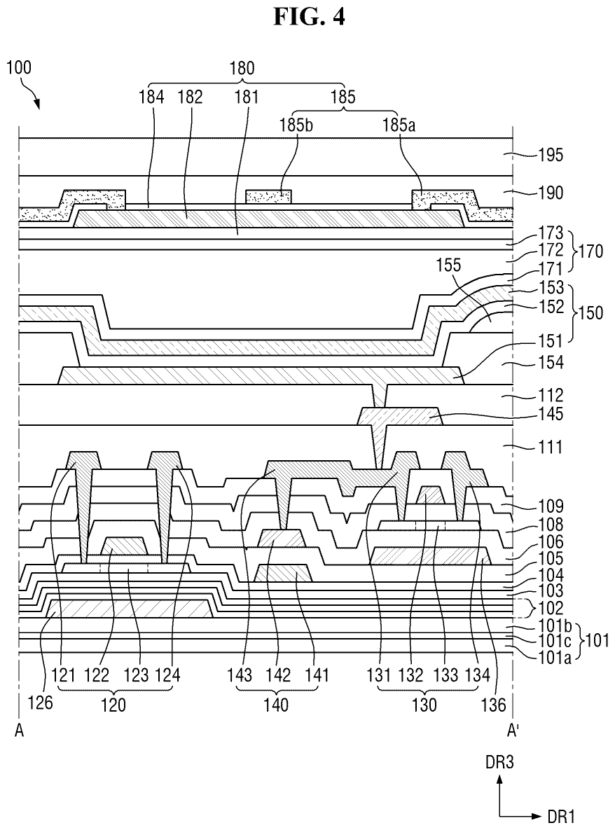

FIG. 4 is a cross-sectional view taken along line A-A′ of FIG. 3.

Referring to FIG. 4, the display panel 100 may include a substrate 101, a first thin-film transistor 120, a second thin-film transistor 130, a light-emitting layer 150, an encapsulation layer 170, and a touch layer 180. The display panel 100 may include at least one inorganic layer between the substrate 101 and the light-emitting layer 150. The at least one inorganic layer may include at least one of a buffer layer 102, a first insulating layer 103, a second insulating layer 104, a third insulating layer 105, a fourth insulating layer 106, a fifth insulating layer 108, and a sixth insulating layer 109; however, the embodiments of this disclosure are not limited thereto. The at least one inorganic layer constituting the touch layer 180 may include at least one of a touch buffer layer 181 and an insulating layer 184; however, the embodiments of this disclosure are not limited thereto.

The substrate 101 may include one or more plastic materials. For example, the substrate 101 may be a multi-substrate including multiple plastic materials, such as polyimide; however, the embodiments of this disclosure are not limited thereto. For example, the substrate 101 may include a first substrate 101a and a second substrate 101b, each including a plastic material, and a third substrate 101c between the first substrate 101a and the second substrate 101b, which includes an inorganic material; however, the embodiments of this disclosure are not limited thereto.

A first light-blocking layer 126 may be disposed on the substrate 101. The first light-blocking layer 126 may prevent light from passing through the first semiconductor layer 123 of the first thin-film transistor 120. For example, the first semiconductor layer 123 may be disposed to overlap with the first light-blocking layer 126. The first light-blocking layer 126 may be a single layer or multiple layers made of molybdenum (Mo), aluminum (Al), chromium (Cr), nickel (Ni), neodymium (Nd), copper (Cu), or any of their alloys, but the embodiments of this disclosure are not limited thereto.

A buffer layer 102 may be disposed on the first light-blocking layer 126. The buffer layer 102 may minimize or delay the diffusion of moisture or oxygen that penetrates into the substrate 101. The buffer layer 102 may be formed by alternately stacking silicon nitride (SiNx) and silicon oxide (SiOx) at least once, but the embodiments of this disclosure are not limited thereto.

A first insulating layer 103 may be disposed on the buffer layer 102. The first insulating layer 103 may prevent a short circuit between the configuration of the first thin-film transistor 120 and the first light-blocking layer 126. The first insulating layer 103 may be made of the same material as the buffer layer 102, but the embodiments of this disclosure are not limited thereto. For example, the first insulating layer 103 may be made of an inorganic material, such as silicon nitride (SiNx) or silicon oxide (SiOx), but the embodiments of this disclosure are not limited thereto.

A first thin-film transistor 120 may be disposed on the first insulating layer 103. The first thin-film transistor 120 may include a first source electrode 121, a first gate electrode 122, a first semiconductor layer 123, and a first drain electrode 124.

The first semiconductor layer 123 may be disposed on the first insulating layer 103. The first semiconductor layer 123 may include a metal oxide semiconductor such as Indium-Gallium-Zinc Oxide (IGZO), or a silicon-based semiconductor material such as amorphous silicon or polycrystalline silicon, but the embodiments of this disclosure are not limited thereto. The first semiconductor layer 123 may include a channel region, a source region, and a drain region.

The polycrystalline semiconductor layer has higher mobility than the amorphous semiconductor layer and the oxide semiconductor layer, so it may have lower power consumption and improved reliability. Thus, the driving transistor may be composed of a polycrystalline semiconductor layer; however, the embodiments of this disclosure are not limited thereto.

A second insulating layer 104 may be disposed on the first semiconductor layer 123. The second insulating layer 104 may be made of the same material as the first insulating layer 103 and may prevent short circuits between the first semiconductor layer 123 and other components of the first thin-film transistor 120.

A first gate electrode 122 may be disposed on the second insulating layer 104. The first gate electrode 122 may be arranged to overlap with the channel region of the first semiconductor layer 123, positioned on the second insulating layer 104. The first gate electrode 122 may be composed of a single layer or multilayer structure that includes materials such as molybdenum (Mo), copper (Cu), titanium (Ti), aluminum (Al), chromium (Cr), gold (Au), nickel (Ni), neodymium (Nd), or their compounds, but the embodiments of this disclosure are not limited to these materials. The first gate electrode 122 may be disposed together with the gate line; however, the embodiments of this disclosure are not limited thereto.

A third insulating layer 105 may be disposed on the first gate electrode 122. The third insulating layer 105 may be made of the same material as the first insulating layer 103 or the second insulating layer 104; however, the embodiments of this disclosure are not limited thereto.

A first source electrode 121 and a first drain electrode 124 may be disposed on the third insulating layer 105.

The first source electrode 121 and the first drain electrode 124 may be electrically connected to the first semiconductor layer 123 through contact holes. The first source electrode 121 and the first drain electrode 124 may be made of a metal material. For example, the first source electrode 121 and the first drain electrode 124 may be composed of a single layer or multiple layers made of any one of molybdenum (Mo), aluminum (Al), chromium (Cr), gold (Au), titanium (Ti), nickel (Ni), neodymium (Nd), copper (Cu), or their alloys, but the embodiments of this disclosure are not limited thereto.

The first source electrode 121 and the first drain electrode 124 may be arranged along with the data line. For example, the data line may be formed in the same layer and made of the same material as the first source electrode 121 and the first drain electrode 124, but the embodiments of this disclosure are not limited thereto.

The storage electrode 140 may be disposed apart from the first thin-film transistor 120. The storage electrode 140 may include a first storage electrode 141, a second storage electrode 142, and a third storage electrode 143.

The first storage electrode 141 may be disposed in the same layer and made of the same material as the first gate electrode 122, but the embodiments of this disclosure are not limited thereto.

The second storage electrode 142 may be disposed on the first storage electrode 141. The second storage electrode 142 may be disposed on the third insulating layer 105, and a capacitance may be formed by using the third insulating layer 105 as a dielectric between the first storage electrode 141 and the second storage electrode 142. The second storage electrode 142 may be made of the same material as the first storage electrode 141, but the embodiments of this disclosure are not limited thereto.

The second thin-film transistor 130 may be disposed spaced apart from the first thin-film transistor 120 and the storage electrode 140. The second thin-film transistor 130 may include a second source electrode 131, a second gate electrode 132, a second semiconductor layer 133, and a second drain electrode 134.

The second light-blocking layer 136 may be disposed in the same layer as the second storage electrode 142.

The second light-blocking layer 136, similar to the first light-blocking layer 126, may prevent light from reaching the second semiconductor layer 133, thereby extending the lifespan of the second thin-film transistor 130. For example, the second semiconductor layer 133 may be disposed overlapping with the second light-blocking layer 136.

The fourth insulating layer 106 may be disposed on the second light-blocking layer 136. The fourth insulating layer 106 may be made of the same material as the first insulating layer 103, the second insulating layer 104, or the third insulating layer 105, but the embodiments of this disclosure are not limited to this.

The second semiconductor layer 133 may be disposed on the fourth insulating layer 106. The second semiconductor layer 133 may include a source region, a drain region, and a channel region between the source and drain regions.

The second semiconductor layer 133 may include a semiconductor material such as a metal oxide semiconductor like Indium-Gallium-Zinc Oxide (IGZO), or a silicon-based semiconductor material such as amorphous silicon or polycrystalline silicon, but the embodiments of this disclosure are not limited thereto.

The fifth insulating layer 108 may be disposed on the second semiconductor layer 133. The fifth insulating layer 108 may be made of the same material as the first insulating layer 103, the second insulating layer 104, the third insulating layer 105, or the fourth insulating layer 106, but the embodiments of this disclosure are not limited thereto.

The second gate electrode 132 may be disposed on the fifth insulating layer 108.

The second gate electrode 132 may be made of the same material as the first gate electrode 122, but the embodiments of this disclosure are not limited thereto. For example, the second gate electrode 132 may be formed as a single layer or multiple layers made from materials such as molybdenum (Mo), copper (Cu), titanium (Ti), aluminum (Al), chromium (Cr), gold (Au), nickel (Ni), neodymium (Nd), or alloys of these materials, but the embodiments of this disclosure are not limited thereto.

The sixth insulating layer 109 may be disposed on the second gate electrode 132. The sixth insulating layer 109 may be made of the same material as the first insulating layer 103, second insulating layer 104, third insulating layer 105, fourth insulating layer 106, or fifth insulating layer 108, but the embodiments of this disclosure are not limited thereto.

The first source electrode 121, the first drain electrode 124, the third storage electrode 143, the second source electrode 131, and the second drain electrode 134 may be disposed on the sixth insulating layer 109.

The third storage electrode 143, the second source electrode 131, and the second drain electrode 134 may be made of the same material as the first source electrode 121 and the first drain electrode 124, and may be disposed on the same layer; however, the embodiments of this disclosure are not limited thereto. For example, the third storage electrode 143, the second source electrode 131 and second drain electrode 134 may be formed as a single layer or multiple layers made from materials such as molybdenum (Mo), aluminum (Al), chromium (Cr), gold (Au), titanium (Ti), nickel (Ni), neodymium (Nd), and copper (Cu) or alloys of these materials, but the embodiments of this disclosure are not limited thereto For example, the third storage electrode 143 and the second source electrode 131 may be directly connected, but the embodiments of this disclosure are not limited thereto.

The first thin-film transistor 120 may be a driving transistor, and the second thin-film transistor 130 may be a switching transistor, but the embodiments of this disclosure are not limited thereto.

The first source electrode 121 and the first drain electrode 124 may have a first protective layer 111 disposed thereon.

The first protective layer 111 may flatten the upper part of the first thin-film transistor 120 and protect the first thin-film transistor 120. The first protective layer 111 may be made of an organic material. For example, the first protective layer 111 may be made of a material such as acrylic resin, epoxy resin, phenolic resin, polyamide resin, or polyimide resin, but the embodiments of this disclosure are not limited thereto.

The second protective layer 112 may be disposed on the first protective layer 111. The second protective layer 112 may be formed of the same material as the first protective layer 111, but the embodiments of this disclosure are not limited thereto.

A connection electrode 145 may be disposed between the first protective layer 111 and the second protective layer 112.

The connection electrode 145 may electrically connect the second thin-film transistor 130 and the light-emitting layer 150. The connection electrode 145 may be made of the same material as the first source electrode 121 and the first drain electrode 124, but the embodiments of this disclosure are not limited thereto.

The connection electrode 145 may be a single layer or multilayer made from materials such as molybdenum (Mo), aluminum (Al), chromium (Cr), gold (Au), titanium (Ti), nickel (Ni), neodymium (Nd), and copper (Cu) or alloys of these materials, but the embodiments of this disclosure are not limited thereto.

The light-emitting layer 150 may be disposed on the second protective layer 112. The light-emitting layer 150 may include an anode electrode 151, an organic layer 152, and a cathode electrode 153.

A second protective layer 112 may have an anode electrode 151 disposed thereon. The anode electrode 151 may be electrically connected to the first thin-film transistor 120 through a contact hole formed in the second protective layer 112. The anode electrode 151 may be a reflective electrode that reflects light, but the embodiments of this disclosure are not limited thereto. The anode electrode 151 may include a laminated structure (Ti/Al/Ti) of aluminum (Al) and titanium (Ti), a laminated structure (ITO/Al/ITO) of aluminum (Al) and ITO, or a high-reflectivity metal material such as APC alloy, and may be formed as a single layer or multiple layers, but the embodiments of this disclosure are not limited thereto.

An organic layer 152 may be disposed on the anode electrode 151. The organic layer 152 may include one or more light-emitting structures (or light-emitting devices or elements) stacked in either a hole-delivery layer and electron-delivery layer order, or the reverse order, on the anode electrode 151. For example, the hole delivery layer may include a hole transport layer, hole injecting layer, electron blocking layer, or P-type charge generating layer, but the embodiments of this disclosure are not limited thereto. For example, the electron delivery layer may include an electron transport layer, electron injecting layer, hole blocking layer, or N-type charge generating layer, but the embodiments of this disclosure are not limited thereto. The organic layer 152 may be an organic light-emitting layer, an inorganic light-emitting layer, a quantum dot light-emitting layer, a micro light-emitting diode, or a micro-mini light-emitting diode, but the embodiments of this disclosure are not limited thereto. For example, the display panel 100 according an embodiment of this disclosure, the organic layer 152 may include an organic light-emitting layer. The organic layer 152 may include a red light-emitting layer, a green light-emitting layer, and a blue light-emitting layer. The organic layer 152 may further include a white light-emitting layer, but the embodiments of this disclosure are not limited thereto.

A cathode electrode 153 may be disposed on organic layer 152. The cathode electrode 153 may be a transparent electrode that transmits light, but the embodiments of this disclosure are not limited to this. For example, the cathode electrode 153 may include a transparent conductive material such as Indium Tin Oxide (ITO) or Indium Zinc Oxide (IZO), or a metal that allows visible light to pass through, but the embodiments of this disclosure are not limited thereto.

The bank 154 may be disposed to expose the anode electrode 151. The bank 154 may define the opening (or light-emitting area) of the sub-pixel and may be disposed to cover the edge portion (or boundary portion) of the anode electrode 151. Each sub-pixel may include a red light-emitting area, a green light-emitting area, and a blue light-emitting area. For example, the sub-pixel may be a pixel, but the term is not limited thereto. The bank 154 may be made of a material containing black pigment or an organic material such as benzocyclobutene resin, polyimide resin, acrylic resin, or photosensitive polymer; however, the embodiments of this disclosure are not limited thereto. Wen made of a material containing black pigments or black dyes, the bank 154 may be a black bank. When made of a material containing black pigments or black dyes, the bank 154 may block light from the outside or block light reflected from the outside, thereby improving the brightness of the display apparatus. A spacer 155 may be further disposed on the bank 154. The spacer may be made of the same material as the bank 154, but the embodiments of this disclosure are not limited thereto.

An encapsulation layer 170 may be disposed on the bank 154 or the light-emitting layer 150. The encapsulation layer 170 may include one or more insulating layers. For example, the encapsulation layer 170 may include a first encapsulation layer 171, a second encapsulation layer 172 located on top of the first encapsulation layer 171, and a third encapsulation layer 173 located on top of the second encapsulation layer 172. The encapsulation layer 170 may include one or more inorganic material layers and one or more organic material layers. For example, the first encapsulation layer 171 and the third encapsulation layer 173 may include inorganic materials, while the second encapsulation layer 172 may include organic materials, but the embodiments of this disclosure are not limited thereto.

A buffer layer 181 may be disposed on encapsulation layer 170. For example, the buffer layer 181 may be disposed on the third encapsulation layer 173. The buffer layer 181 may be made of the same material as the buffer layer 102, but the embodiments of this disclosure are not limited thereto. An insulating layer 184 may be disposed on the buffer layer 181. The insulating layer 184 may prevent shorts between the touch electrodes. The insulating layer 184 may be made of silicon oxide (SiOx), silicon nitride (SiNx), or a multilayer thereof, but the embodiments of this disclosure are not limited thereto. A first touch electrode 185 may be disposed on the insulating layer 184. The first touch electrode 185 may include a first-a touch electrode 185a extending in a first direction and a second-b touch electrode 185b extending in a second direction different from the first direction.

A second touch electrode 182 may be disposed between the buffer layer 181 and the insulating layer 184.

The second touch electrode 182 may be electrically connected to the first-a touch electrode 185a through a contact hole formed in the insulating layer 184. For example, the first-a touch electrode 185a and the second touch electrode 182 may extend in the first direction.

The first touch electrode 185 and the second touch electrode 182 may include metal materials. For example, they may be formed of titanium (Ti), nickel (Ni), aluminum (Al), or an alloy thereof and may be composed of three layers, such as titanium (Ti)/aluminum (Al)/titanium (Ti), but the embodiments of this disclosure are not limited thereto.

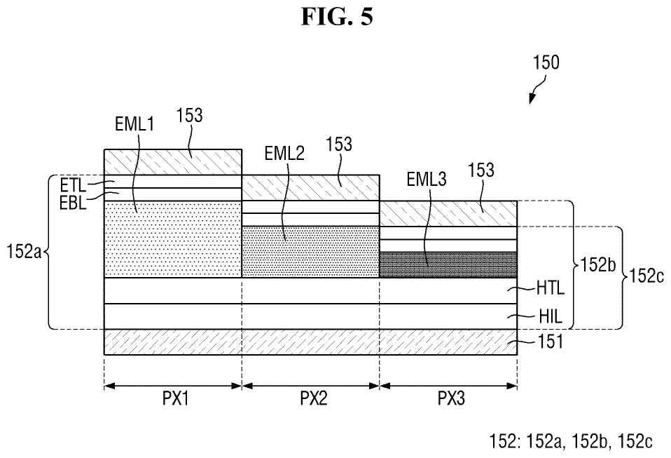

FIG. 5 is a detailed cross-sectional view of the lighting-emitting layer of FIG. 4.

Referring to FIG. 5, the light-emitting layer 150 may extend across a first sub-pixel PX1, a second sub-pixel PX2, and a third sub-pixel PX3.

The thickness of the light-emitting layer 150 may differ in each sub-pixel PX1, PX2, and PX3, but the embodiments of this disclosure are not limited thereto, and the thickness of the light-emitting layer 150 in each sub-pixel PX1, PX2, and PX3 may also be the same.

The organic layer 152 may include a first organic layer 152a disposed in the first sub-pixel PX1, a second organic layer 152b disposed in the second sub-pixel PX2, and a third organic layer 152c disposed in the third sub-pixel PX3. The light-emitting layers EML1, EML2, and EML3 in the respective organic layers 152a, 152b, and 152c may be physically separated, but the lower and upper layers of the light-emitting layers EML1, EML2, and EML3 may be integrally formed across the sub-pixels PX1, PX2, and PX3. The light-emitting layers EML1, EML2, and EML3 may differ in thickness. For example, the thickness of the first light-emitting layer EML1 may be the largest, followed by the second light-emitting layer EML2, and the thickness of the third light-emitting layer EML3 may be the smallest, but the embodiments of this disclosure are not limited thereto.

The hole injection layer HIL may be disposed on the anode electrode 151. The hole injection layer HIL may be positioned between the anode electrode 151 and the light-emitting layers EML1, EML2, and EML3. The hole injection layer HIL may be integrally formed across the sub-pixels PX1, PX2, and PX3. For example, the hole injection layer HIL may be made of a material selected from a group of MTDATA, CuPc, TCTA, NPB (NPD), HATCN, TDAPB, PEDOT/PSS, F4TCNQ, and N-(biphenyl-4-yl)-9,9-dimethyl-N-(4-(9-phenyl-9H-carbazole-3-yl)phenyl)-9H-fluorene-2-amine, but the embodiments of this disclosure are not limited thereto.

The hole transport layer HTL may be disposed on the hole injection layer HIL. The hole transport layer HTL may be positioned between the hole injection layer HIL and the light-emitting layers EML1, EML2, and EML3. The hole transport layer HTL may be integrally formed across the sub-pixels PX1, PX2, and PX3. be made of one or more materials selected from the aryamine-based compounds (Arylamine Base) such as NPB (N,N-naphthyl-N,N′-phenyl benzidine), TPD (N,N′-bis-(3-methylphenyl)-N,N′-bis-(phenyl)-benzidine), PPD, TTBND, FFD, p-dmDPS, TAPC, the starburst aromatic amines (Starburst aromatic amine) such as TCTA, PTDATA, TDAPB, TDBA, 4-a, TCTA, spiro and ladder-type materials (Spiro and Ladder Type) like Spiro-TPD, Spiro-mTTB, Spiro-2, NPD (N,N-dinaphthyl-N,N′-diphenyl benzidine), s-TAD, and MTDATA (4,4′,4″-Tris(N-3-methylphenyl-N-phenyl-amino)-triphenylamine); however, the embodiments of this disclosure are not limited thereto.

The light-emitting layers EML1, EML2, and EML3 may be disposed on the hole transport layer HTL. The first sub-pixel PX1 may have the first light-emitting layer EML1, the second sub-pixel PX2 may have the second light-emitting layer EML2, and the third sub-pixel PX3 may have the third light-emitting layer EML3.

The light-emitting layers EML1, EML2, and EML3 may differ in thickness. For example, the first light-emitting layer EML1 may have a thickness of 600 to 800 Å, the second light-emitting layer EML2 may have a thickness of 300 to 500 Å, and the third light-emitting layer EML3 may have a thickness of 100 to 300 Å, but the embodiments of this disclosure are not limited thereto.

The first light-emitting layer EML1, the second light-emitting layer EML2, and the third light-emitting layer EML3 may include materials that emit light in the visible light spectrum by combining holes and electrons, which are transported separately.

An electron blocking layer EBL may be disposed on each of the light-emitting layers EML1, EML2, and EML3. The electron blocking layer EBL may be integrally disposed across the sub-pixels PX1, PX2, and PX3.

An electron transport layer ETL may be disposed on the electron blocking layer EBL. The electron transport layer ETL may be integrally (or commonly) disposed across the sub-pixels PX1, PX2, and PX3. The electron transport layer ETL may be made of anthracene derivatives and lithium quinolate (Liq), or one or more of oxadiazole, triazole, phenanthroline, benzoxazole, benzthiazole, or benzimidazole (e.g., 2-[4-(9,10-Di-2-naphthalenyl-2-anthracenyl)phenyl]-1-phenyl-1H-benzimidazole); however, the embodiments of this disclosure are not limited thereto.

A cathode electrode 153 may be disposed on the electron transport layer ETL.

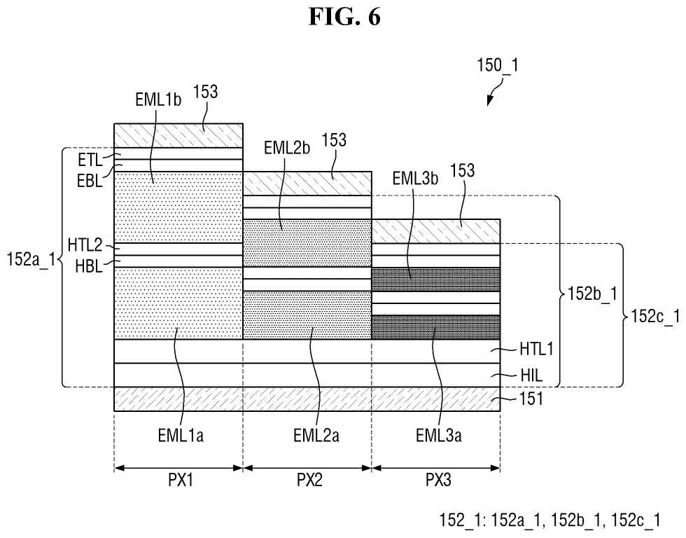

FIG. 6 is a detailed cross-sectional view of the light-emitting layer according to an alternative embodiment.

Referring to FIGS. 5 and 6, the organic layer 152_1 may include a first organic layer 152a_1 disposed in the first sub-pixel PX1, a second organic layer 152b_1 disposed in the second sub-pixel PX2, and a third organic layer 152c_1 disposed in the third sub-pixel PX3.

The light-emitting layers in respective organic layers 152a_1, 152b_1, and 152c_1 may be physically separated, but the lower and upper layers of the light-emitting layers may be integrally formed across the sub-pixels PX1, PX2, and PX3. The light-emitting layers may differ in thickness; however, the embodiments of this disclosure are not limited thereto. For example, the first light-emitting layer in the first sub-pixel may have the greatest thickness, followed by the second light-emitting layer in the second sub-pixel, with the third light-emitting layer in the third sub-pixel having the smallest thickness, but the embodiments of this disclosure are not limited thereto. Additionally, the light-emitting layers in each organic layer 152a_1, 152b_1, and 152c_1 may include two or more layers.

The hole injection layer HIL may be disposed on the anode electrode 151. The hole injection layer HIL may be positioned between the anode electrode 151 and the light-emitting layers EML1a, EML2a, and EML3a. The hole injection layer HIL may be integrally formed across the sub-pixels PX1, PX2, and PX3. may be made of a material selected from a group including MTDATA, CuPc, TCTA, NPB (NPD), HATCN, TDAPB, PEDOT/PSS, F4TCNQ, N-(biphenyl-4-yl)-9,9-dimethyl-N-(4-(9-phenyl-9H-carbazole-3-yl)phenyl)-9H-fluorene-2-amine, but the embodiments of this disclosure are not limited thereto.

The first hole transport layer HTL1 may be disposed on the hole injection layer HIL. The first hole transport layer HTL1 may be positioned between the hole injection layer HIL and the light-emitting layers EML1a, EML2a, and EML3a. The first hole transport layer HTL1 may be integrally formed across the sub-pixels PX1, PX2, and PX3. The first hole transport layer (HTL1) may be made of one or more materials selected from a group including aryamine-based compounds such as NPB (N,N-naphthyl-N,N′-phenyl benzidine), TPD (N,N′-bis-(3-methylphenyl)-N,N′-bis-(phenyl)-benzidine), PPD, TTBND, FFD, p-dmDPS, TAPC, starburst aromatic amines such as TCTA, PTDATA, TDAPB, TDBA, 4-a, TCTA, spiro and ladder-type materials such as Spiro-TPD, Spiro-mTTB, Spiro-2, as well as NPD (N,N-dinaphthyl-N,N′-diphenyl benzidine), s-TAD, and MTDATA (4,4′,4″-Tris(N-3-methylphenyl-N-phenyl-amino)-triphenylamine), but the embodiments of this disclosure are not limited thereto.

The light-emitting layers EML1a, EML2a, and EML3a may be disposed on the first hole transport layer HTL1. The first sub-pixel PX1 may have the 1-1 light-emitting layer EML1a, the second sub-pixel PX2 may have the 2-1 light-emitting layer EML2a, and the third sub-pixel PX3 may have the 3-1 light-emitting layer EML3a. The light-emitting layers EML1a, EML2a, and EML3a may be substantially identical to the respective light-emitting layers EML1, EML2, and EML3 in FIG. 4.

The light-emitting layers EML1a, EML2a, and EML3a may differ in thickness; however, the embodiments of this disclosure are not limited thereto. For example, the 1-1 light-emitting layer EML1a may be formed with a thickness of 600 to 800 Å, the 2-1 light-emitting layer EML2a may be formed with a thickness of 300 to 500 Å, and the 3-1 light-emitting layer EML3a may be formed with a thickness of 100 to 300 Å, but the embodiments of this disclosure are not limited thereto.

A hole blocking layer HBL may be disposed on each of the light-emitting layers EML1a, EML2a, and EML3a. The hole blocking layer HBL may be integrally disposed across the sub-pixels PX1, PX2, and PX3.

A second hole transport layer HTL2 may be disposed on the hole-blocking layer HBL. The second hole transport layer HTL2 may be positioned between the hole blocking layer HBL and the light-emitting layers EML1b, EML2b, and EML3b. The second hole transport layer HTL2 may be integrally formed across the sub-pixels PX1, PX2, and PX3. The material of the second hole transport layer HTL2 may be the same as that of the first hole transport layer HTL1, but the embodiments of this disclosure are not limited thereto.

The light-emitting layers EML1b, EML2b, and EML3b may be disposed on the second hole transport layer HTL2. The first sub-pixel PX1 may have the 1-2 light-emitting layer EML1b, the second sub-pixel PX2 may have the 2-2 light-emitting layer EML2b, and the third sub-pixel PX3 may have the 3-2 light-emitting layer EML3b. The light-emitting layers EML1b, EML2b, and EML3b may be identical to the light-emitting layers EML1a, EML2a, and EML3a, respectively, but the embodiments of this disclosure are not limited thereto.

The light-emitting layers EML1b, EML2b, and EML3b may differ in thickness; however, the embodiments of this disclosure are not limited thereto. For example, the 1-2 light-emitting layer EML1b may be formed with a thickness of 600 to 800 Å, the 2-2 light-emitting layer EML2b may be formed with a thickness of 300 to 500 Å, and the 3-2 light-emitting layer EML3b may be formed with a thickness of 100 to 300 Å, but the embodiments of this disclosure are not limited thereto.

An electron blocking layer EBL may be disposed on each of the light-emitting layers EML1b, EML2b, and EML3b. The electron blocking layer EBL may be integrally disposed across the sub-pixels PX1, PX2, and PX3.

An electron transport layer ETL may be disposed on the electron blocking layer EBL. The electron transport layer ETL may be integrally disposed across the sub-pixels PX1, PX2, and PX3. The electron transport layer ETL may be made of anthracene derivatives and lithium quinolate (Liq), or one or more of oxadiazole, triazole, phenanthroline, benzoxazole, benzthiazole, or benzimidazole (e.g., 2-[4-(9,10-Di-2-naphthalenyl-2-anthracenyl)phenyl]-1-phenyl-1H-benzimidazole); however, the embodiments of this disclosure are not limited thereto.

A cathode electrode 153 may be disposed on the electron transport layer ETL. The cathode electrode 153 may be a transparent electrode that transmits light, but the embodiments of this disclosure are not limited to this. For example, the cathode electrode 153 may include a transparent conductive material such as Indium Tin Oxide (ITO) or Indium Zinc Oxide (IZO), or a metal that allows visible light to pass through, but the embodiments of this disclosure are not limited thereto.

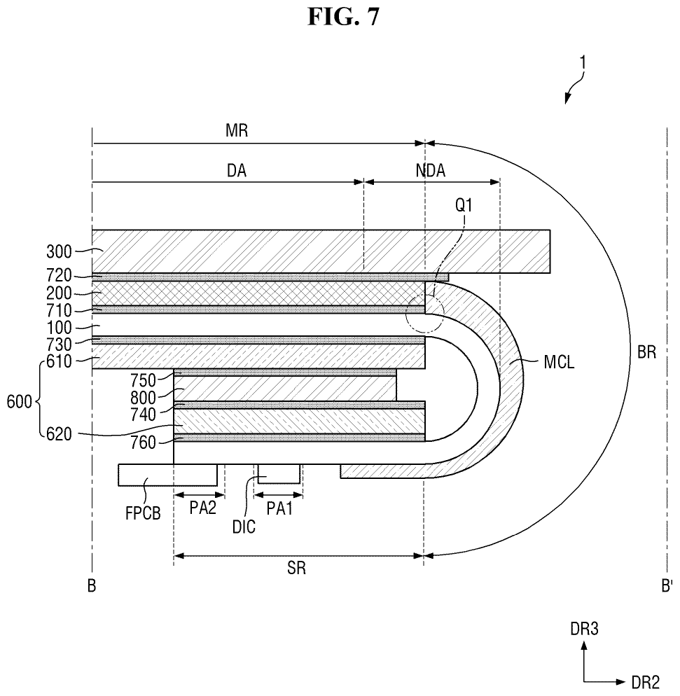

FIG. 7 is a cross-sectional view taken along line B-B′ of FIG. 3.

Referring to FIG. 3 and FIG. 7, the display apparatus 1 may include a display panel 100, a polarization layer 200, a cover layer 300, a backplate layer 600, a plate layer 800, and bonding layers 710, 720, 730, 740, 750, and 760.

The bending region BR of the display panel 100 may have a curved shape and may be bent in the thickness direction. The main region MR and the sub-region SR of the display panel 100 may overlap with each other.

A polarization layer 200 may be disposed in the main region MR of the display panel 100. The polarization layer 200 may polarize light emitted from the display panel 100 at a polarization angle. The polarization layer 200 may emit light polarized at the polarization angle to the outside. The polarization layer 200 may include a function to block the reflection of light, except for light polarized at the polarization angle, from the external light. The polarization layer 200 may include a first phase delay layer, a second phase delay layer on the first phase delay layer, and a polarization layer on the second phase delay layer. In FIG. 7, the polarization layer 200 and the display panel 100 are shown as being separate, but the configuration is not limited thereto, and the polarization layer 200 may be included in the display panel 100.

A cover layer 300 may be disposed on the polarization layer 200. The cover layer 300 may be made of a glass material, such as glass or quartz, but the embodiments of this disclosure are not limited thereto and may also be made of plastic material. The cover layer 300 may be disposed on top of the display panel 100 to protect the components positioned below the cover layer 300 from the outside. The cover layer 300 may be a chemically-strengthened cover layer, but the embodiments of this disclosure are not limited thereto. The cover layer 300 may be a cover window, window cover, or cover member, but the embodiments of this disclosure are not limited thereto.

To improve the durability of the cover layer 300, the display apparatus 1 may further include at least one additional layer on the cover layer 300. For example, the display apparatus 1 may include a film layer or coating layer on the cover layer 300, but the embodiments of this disclosure are not limited thereto.

The side of the cover layer 300 may protrude outwardly more than the side of the display panel 100. For example, the side of the cover layer 300 may protrude further outward than the end of the bending region BR of the display panel 100, but the embodiments of this disclosure are not limited thereto.

A backplate layer 600 may be disposed beneath the display panel 100. The backplate layer 600 is disposed beneath the display panel 100 to support the display panel 100. The backplate layer 600 may include a material capable of supporting the display panel 100. For example, the backplate layer 600 may include polyethylene terephthalate PET, polyimide PI, or polycarbonate PC, but the embodiments of this disclosure are not limited thereto. The backplate layer 600 may maintain the curvature of the display panel 100 constant during the folding of the display apparatus 1 and suppress wrinkles that may occur on the upper surface of the display panel 100.

The backplate layer 600 may include a first backplate layer 610 on the main region MR and a second backplate layer 620 on the sub-region SR. The first backplate layer 610 may be disposed between the main region MR of the display panel 100 and the plate layer 800, and the second backplate layer 620 may be disposed between the sub-region SR of the display panel 100 and the plate layer 800. The backplate layer 600 may not be disposed on the bending region BR, but the embodiments of this disclosure are not limited thereto.

A plate layer 800 may be disposed between the first backplate layer 610 and the second backplate layer 620. The plate layer 800 may include metal. For example, the plate layer 800 may include stainless steel, but the embodiments of this disclosure are not limited thereto.

Bonding layers may be further disposed between the aforementioned members 100, 200, 300, 600, and 800. The bonding layers may include a first bonding layer 710, a second bonding layer 720, a third bonding layer 730, a fourth bonding layer 740, a fifth bonding layer 750, and a sixth bonding layer 760.

The first bonding layer 710 may be disposed between the display panel 100 and the polarization layer 200. The first bonding layer 710 may connect or bond the display panel 100 and the polarization layer 200.

The second bonding layer 720 may be disposed between the polarization layer 200 and the cover layer 300. The second bonding layer 720 may connect or bond the polarization layer 200 and the cover layer 300. While the end of the second bonding layer 720 extends to the bending region BR, the end of the polarization layer 200 may be aligned with the boundary between the main region MR and the bending region BR; however, the embodiments of this disclosure are not limited thereto. The end of the second bonding layer 720 may protrude toward the bending region BR compared to (or more than) the end of the polarization layer 200.

The third bonding layer 730 may be disposed between the first backplate layer 610 and the display panel 100. The third bonding layer 730 may connect or bond the first backplate layer 610 and the display panel 100.

The fourth bonding layer 740 may be disposed between the second backplate layer 620 and the plate layer 800. The fourth bonding layer 740 may connect or bond the second backplate layer 620 and the plate layer 800.

The fifth bonding layer 750 may be disposed between the first backplate layer 610 and the plate layer 800. The fifth bonding layer 750 may connect or bond the first backplate layer 610 and the plate layer 800.

The sixth bonding layer 760 may be disposed between the second backplate layer 620 and the display panel 100. The sixth bonding layer 760 may connect or bond the second backplate layer 620 and the display panel 100.

The first bonding layer 710 and the second bonding layer 720 may each include a transparent adhesive, but the embodiments of this disclosure are not limited thereto. For example, the transparent adhesive may be a transparent resin (OCR) or an optically clear adhesive (OCA), but the embodiments of this disclosure are not limited thereto. The third bonding layer 730, the fourth bonding layer 740, the fifth bonding layer 750, and the sixth bonding layer 760 may each include a pressure-sensitive adhesive (PSA), but the embodiments of this disclosure are not limited thereto.

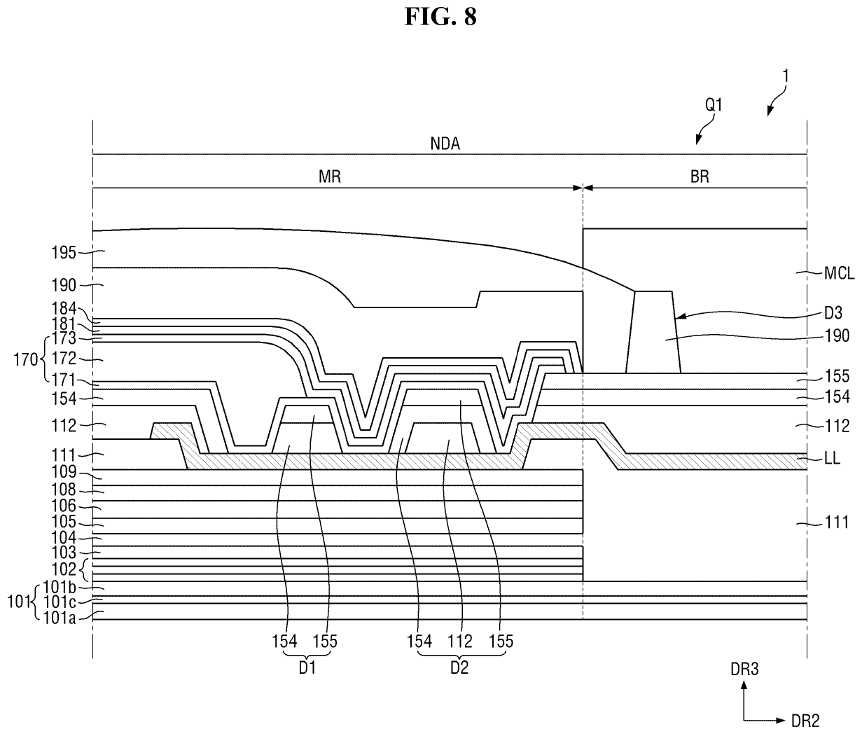

A covering layer MCL may be disposed on one surface of the bending region BR of the display panel 100. The covering layer MCL may include a plastic material. The covering layer MCL may be formed or coated on one surface of the bending region BR of the display panel 100 so as to cover the bending region BR of the display panel 100. A link line (e.g., LL in FIG. 8) may be disposed in the bending region BR. The covering layer MCL may protect the link line LL from external impact while preventing moisture penetration into the link line LL. Additionally, when the bending region BR of the display panel 100 is bent into a curved shape with a constant curvature radius, the covering layer MCL may position the link line LL in the neutral plane. Within the bending region BR, a neutral plane where tensile and compressive forces are zero is formed, and since the link line LL is positioned on the neutral plane, the link line LL experiences zero bending stress when the display panel 100 is bent, allowing the display panel 100 to bend without being damaged by bending stress.

The covering layer MCL may be in contact with the sides of the polarization layer 200 and the first bonding layer 710. The covering layer MCL may be partially extended to the sub-region SR. The covering layer MCL may be in contact with the bottom surface of the second bonding layer 720. The covering layer MCL may overlap with the second bonding layer 720.

In the first pad area PA1 of the sub-region SR, the data driving unit DIC may be disposed, and in the second pad area PA2, the flexible printed circuit board FPCB may be disposed. The flexible printed circuit board FPCB may be electrically connected to the pads on the display panel 100 through anisotropic conductive film ACF. The covering layer MCL may not overlap with the data driving unit DIC, but the embodiments of this disclosure are not limited to this.

FIG. 8 is an enlarged cross-sectional view of Q1 area of FIG. 7. FIG. 8 shows both the main region MR and the bending region BR of the display apparatus 1. The bending region BR in FIG. 7 has a curved shape, but for ease of explanation, the bending region BR is illustrated flat in FIG. 8.

Referring to FIGS. 4, 7, and 8, the inorganic layers 102, 103, 104, 105, 106, 108, and 109 may not be disposed in the bending region BR. Therefore, the first protective layer 111 may be in direct contact with the substrate 101 in the bending region BR.

The link line LL may be disposed on the first protective layer 111. The link line LL may be a line connecting a pad (or data pad) that is connected to the data driving unit DIC in FIG. 7 to a data line in the display area DA. The link line LL may be positioned on the same layer as the connecting electrode 145 in FIG. 4, but the embodiments of this disclosure are not limited to this, and the link line LL may also be positioned on the same layer as the first source electrode 121. The link line LL may be in contact with the side of the first protective layer 111 in the main region MR and with part of the upper surface of the first protective layer 111, but the embodiments of this disclosure are not limited to this. In this disclosure, being on the same layer may also include the concept of containing the same material.

A second protective layer 112 may be disposed on the link line LL. The second protective layer 112 may be disposed in both the main region MR and the bending region BR. The second protective layer 112 in the main region MR may be in direct contact with the end of the link line LL.

Two dams D1 and D2 may be disposed in the main region MR adjacent to the bending region BR. The first dam D1 may be disposed between the display area DA (see FIG. 3) and the bending region BR, and the second dam D2 may be disposed between the first dam D1 and the bending region BR. FIG. 8 illustrates two dams, D1 and D2, but the embodiments of this disclosure are not limited to this, and one, three, or more dams may be disposed.

The second protective layer 112 may form the first layer of the second dam D2. The second protective layer 112 may be disposed across the main region MR and the bending region BR.

A bank 154 may be disposed on the second protective layer 112. The bank 154 may be disposed on both the main region MR and the bending region BR. In the main region MR, the bank 154 may form the first layer of the first dam D1 and the second layer of the second dam D2. In the second dam D2, the second layer, i.e., the bank 154, may be disposed to cover the first layer, i.e., the second protective layer 112, but the embodiments of this disclosure are not limited thereto. For example, the second layer, i.e., the bank 154, may cover the upper surface of the first layer, i.e., the second protective layer 112, cover or completely cover one side of the second direction DR2, and partially cover the opposite side of the second direction DR2, but the embodiments of this disclosure are not limited to this. In this disclosure, the spacer 155 is illustrated as constituting the dams D1 and D2, but the embodiments of this disclosure are not limited thereto. A spacer 155 may be disposed on bank 154. The spacer 155 may be disposed in the main region MR and the bending region BR. The spacer 155 may constitute the second layer of the first dam D1 and the third layer of the second dam D2, but the embodiments of this disclosure are not limited thereto.

An encapsulation layer 170 may be disposed on the spacer 155. The first encapsulation layer 171 is disposed in the main region MR and may not be disposed in the bending region BR. The first encapsulation layer 171 may be in direct contact with the first dam D1 and the second dam D2. The second encapsulation layer 172 may be disposed up to a part of the first dam D1 or may overlap with part of the first dam D1. The third encapsulation layer 173 is disposed in the main region MR and may not be disposed in the bending region BR. The third encapsulation layer 173 may be in contact with or in direct contact with the first encapsulation layer 171 on the first dam D1 and the second dam D2.

An inorganic layer may be disposed on the encapsulation layer 170. The inorganic layer is disposed in the main region MR and may not be disposed in the bending region BR. The inorganic layer may include a buffer layer 181 and an insulating layer 184.

The first organic layer 190 may be disposed on the insulating layer 184. The first organic layer 190 may be made of a material containing acrylic resin, epoxy resin, phenolic resin, polyamide resin, or polyimide resin, but the embodiments of this disclosure are not limited thereto.

The first organic layer 190 is disposed in the main region MR and may constitute the third dam D3 in the bending region BR. The third dam D3 is disposed on the spacer 155 and may be spaced apart by a predetermined distance from the boundary between the bending region BR and the main region MR, but the embodiments of this disclosure are not limited thereto. The third dam D3 may be an organic layer dam or a touch organic layer dam. In the third dam D3, the second organic layer 195 may extend up to the third dam D3.

The second organic layer 195 may be disposed on the first organic layer 190. The second organic layer 195 may be made of a material containing acrylic resin, epoxy resin, phenolic resin, polyamide resin, or polyimide resin, but the embodiments of this disclosure are not limited thereto.

The second organic layer 195 may be in contact with or directly in contact with the side of the third dam D3. In the bending region BR, the second organic layer 195 may be in contact with or directly in contact with the side of the third dam D3, the upper surface of the spacer 155, and the side of the first organic layer 190.

A covering layer MCL may be disposed on the second organic layer 195. The covering layer MCL is disposed in the bending region BR and may not be disposed in the main region MR. The covering layer MCL may be in contact with or directly in contact with the upper and side surfaces of the third dam D3, the upper surface of the second organic layer 195, and the upper surface of the spacer 155.

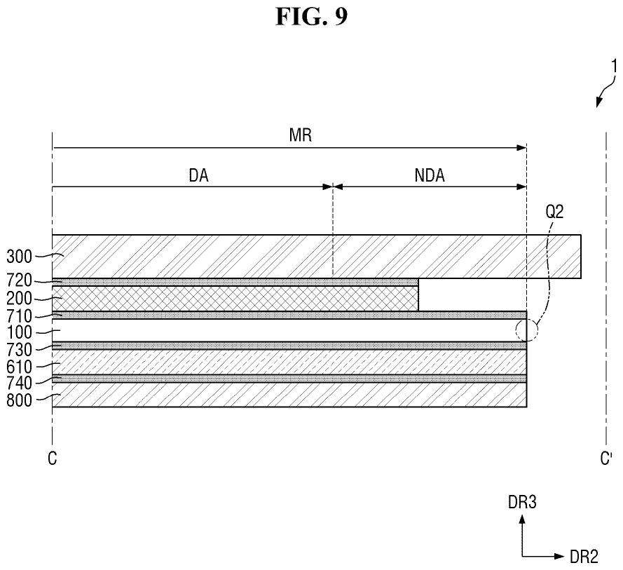

FIG. 9 is a cross-sectional view taken along line C-C′ of FIG. 3. FIG. 9 illustrates the main region MR including the display area DA and non-display area NDA. FIG. 9 is a cross-sectional view of the right region of the display apparatus 1. The cross-sectional view of the right region of the display apparatus 1 may be substantially identical to the cross-sectional views of the left and upper regions of the display apparatus 1, but the embodiments of this disclosure are not limited thereto.

Referring to FIG. 9, the end of the display panel 100 may protrude outward compared to the end of the polarization layer 200 (or in comparison to the end of the polarization layer 200 or beyond the end of the polarization layer 200). In FIG. 9, the end of the second bonding layer 720 is shown as aligned with the end of the polarization layer 200, but the embodiments of this disclosure are not limited to this, and the end of the second bonding layer 720 may protrude outward compared to the end of the polarization layer 200 (or beyond the end of the polarization layer 200).

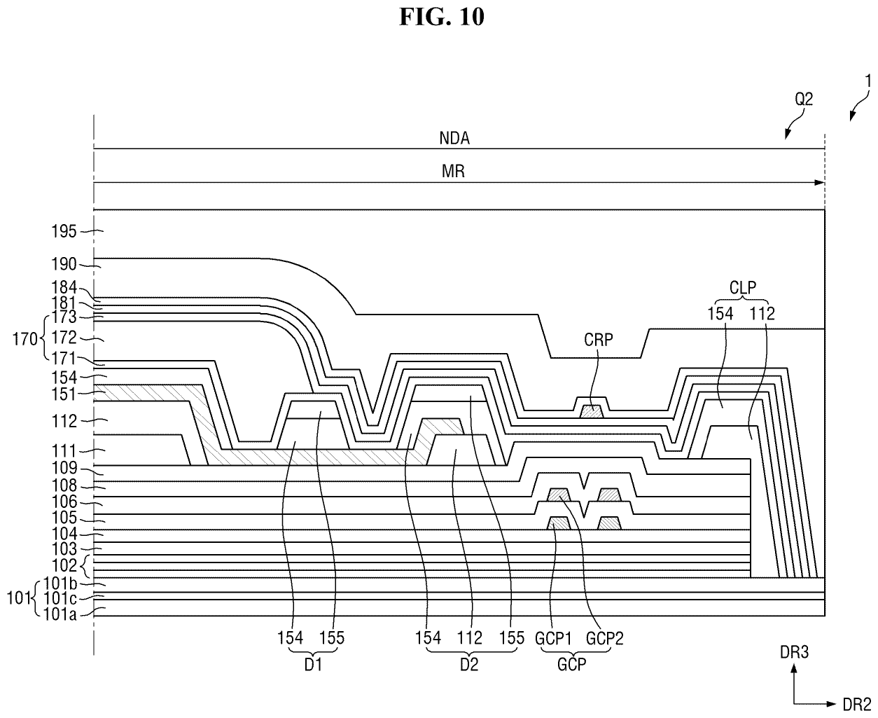

FIG. 10 is an enlarged cross-sectional view of Q2 area of FIG. 9.

Referring to FIG. 9 and FIG. 10, the display panel 100 (see FIG. 9) according to an embodiment may further include a cladding portion CLP. The cladding portion CLP may be composed of a first layer, the second protective layer 112, and a second layer, the bank 154. However, the embodiments of this disclosure are not limited thereto, and the first protective layer 111 or spacer 155 may also further form the cladding portion CLP.

At least one of the inorganic layers 102, 103, 104, 105, 106, 108, 109 may not extend to the end of the substrate 101. The second protective layer 112 of the cladding portion CLP may be in contact or directly in contact with the sides of at least one inorganic layer 102, 103, 104, 105, 106, 108, and 109 and may also be in contact or directly in contact with the upper surface of the substrate 101. The second substrate portion 101b of the substrate 101 includes organic material, and since the cladding portion CLP also contains organic material, the contact or direct contact between the second protective layer 112 of the cladding portion CLP and the second substrate portion 101b may improve the delamination between at least one inorganic layer 102, 103, 104, 105, 106, 108, and 109.

The first encapsulation layer 171 and the third encapsulation layer 173 may extend to the outside of the cladding portion CLP, but may not extend to the end of the substrate 101, but the embodiments of this disclosure are not limited thereto. The first encapsulation layer 171 and the third encapsulation layer 173 may each be in contact with the substrate 101, but the embodiments of this disclosure are not limited thereto. The buffer layer 181 and the insulation layer 184 may extend to the outside of the cladding portion CLP but may not extend to the end of the substrate 101, but the embodiments of this disclosure are not limited thereto. The buffer layer 181 and the insulation layer 184 may each be in contact with the substrate 101, but the embodiments of this disclosure are not limited thereto.

Crack prevention patterns GCP1 and GCP2 may be further disposed between the cladding portion CLP and the second dam D2. The other crack prevention patterns GCP1 and GCP2 may include the first crack prevention pattern GCP1, located in the same layer as the first gate electrode 122 (see FIG. 4), and the second crack prevention pattern GCP2, located in the same layer as the second shading layer 136 (see FIG. 4). Additionally, a crack detection pattern CRP may be further disposed on the other crack prevention patterns GCP1 and GCP2. The crack detection pattern CRP may be located in the same layer as the second touch electrode 182 (see FIG. 4), but the embodiments of this disclosure are not limited thereto. In some embodiments, the other crack prevention patterns GCP1 and GCP2 may be omitted. In such cases, the cladding portion CLP may extend further toward the second dam D2, which provides an advantage. The other crack prevention patterns GCP1 and GCP2 may be gate crack prevention patterns, but the embodiments of this disclosure are not limited thereto.

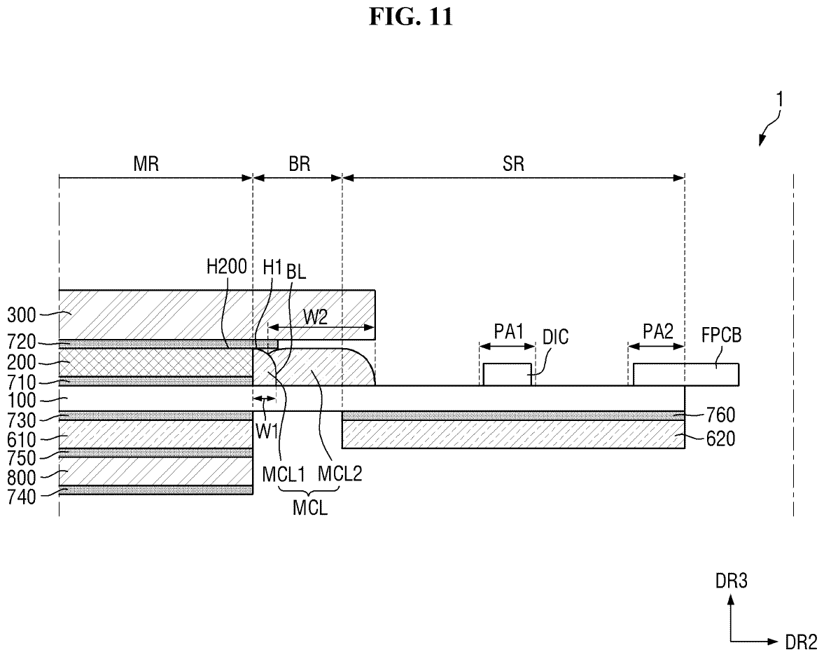

FIG. 11 is a cross-sectional view of a display apparatus according to an embodiment;

FIG. 11 shows a cross-section of the display apparatus 1 according to FIG. 7 in the state of not being bent.

Referring to FIG. 11, the covering layer MCL of the display apparatus 1 according to an embodiment may include a first covering layer MCL1 and a second covering layer MCL2.

The first covering layer MCL1 may be in contact with or in direct contact with the side of the polarization layer 200 and the first bonding layer 710. The end of the second bonding layer 720 may protrude toward the bending region BR compared to (or more than) the end of the polarization layer 200. In the bending region BR, the first covering layer MCL1 may be in contact with or directly contact the second bonding layer 720. The surface height of the first covering layer MCL1 may be aligned with the surface height of the polarization layer 200. The surface height of the second covering layer MCL2 may be higher than the surface height of the first covering layer MCL1, but the embodiments of this disclosure are not limited thereto.

The second covering layer MCL2 may be in contact with the first covering layer MCL1.

The first covering layer MCL1 and the second covering layer MCL2 may include different materials. For example, the first covering layer MCL1 and the second covering layer MCL2 may be formed in different processes, but the embodiments of this disclosure are not limited thereto.

The first covering layer MCL1 and the second covering layer MCL2 are formed in different processes, with the first covering layer MCL1 being formed first and then the second covering layer MCL2, so a boundary BL may exist between the first and second covering layers as shown in FIG. 11. Furthermore, the first covering layer MCL1 and the second covering layer MCL2 may each have a reduced thickness at the boundary BL therebetween compared to the central part of each covering layer (MCL1, MCL2). For example, the first covering layer MCL1 and the second covering layer MCL2 may have a concave or recessed shape downward at the boundary therebetween.

Hereinafter, the manufacturing process of the first covering layer MCL1 and the second covering layer MCL2 is described.

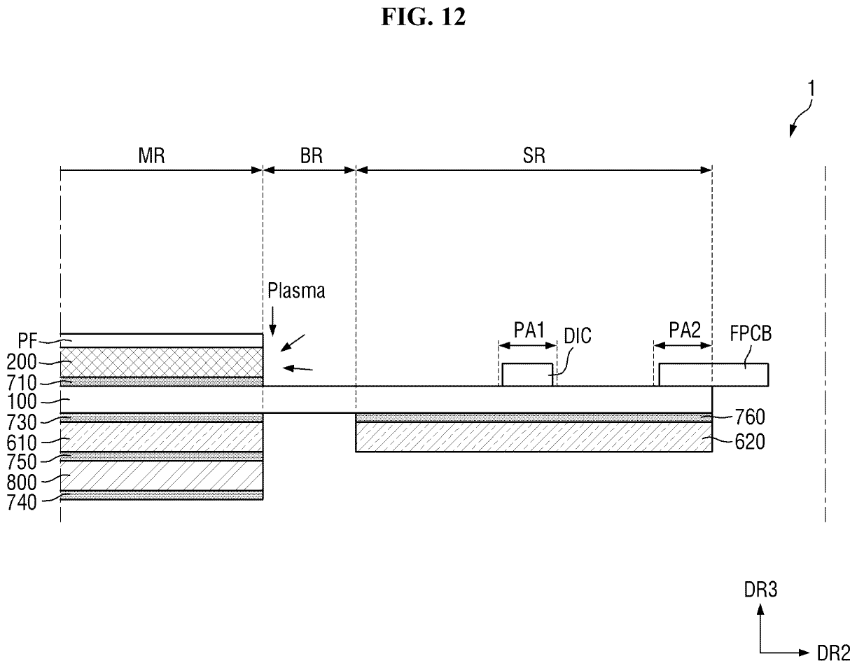

FIGS. 12 to 15 are cross-sectional views for explaining the manufacturing method of the display apparatus of FIG. 11.

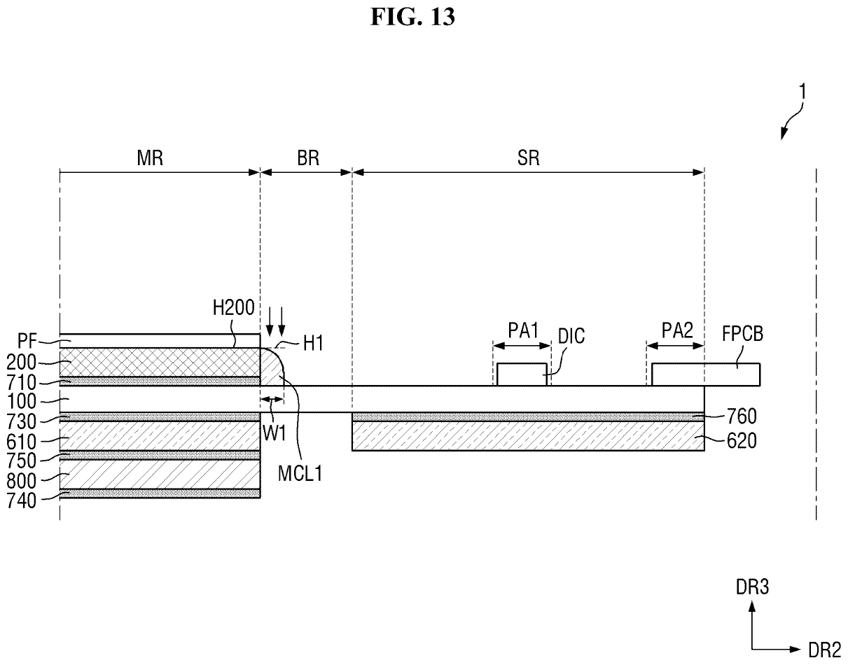

Referring to FIGS. 11 and 12, a protective film PF may be disposed on the polarization layer 200. Before forming the first covering layer MCL1 shown in FIG. 13, plasma treatment may be applied to the side surface of the polarization layer 200 to ensure good contact between the first covering layer MCL1 and the polarization layer 200, but the embodiments of this disclosure are not limited thereto.

Next, as shown in FIGS. 11 and 13, the first covering layer MCL1 may be formed (indicated by arrows) on the side surfaces of the polarization layer 200 and the first bonding layer 710. The first covering layer MCL1 may be formed on the bending region BR to contact the side surfaces of the polarization layer 200 and the first bonding layer 710.

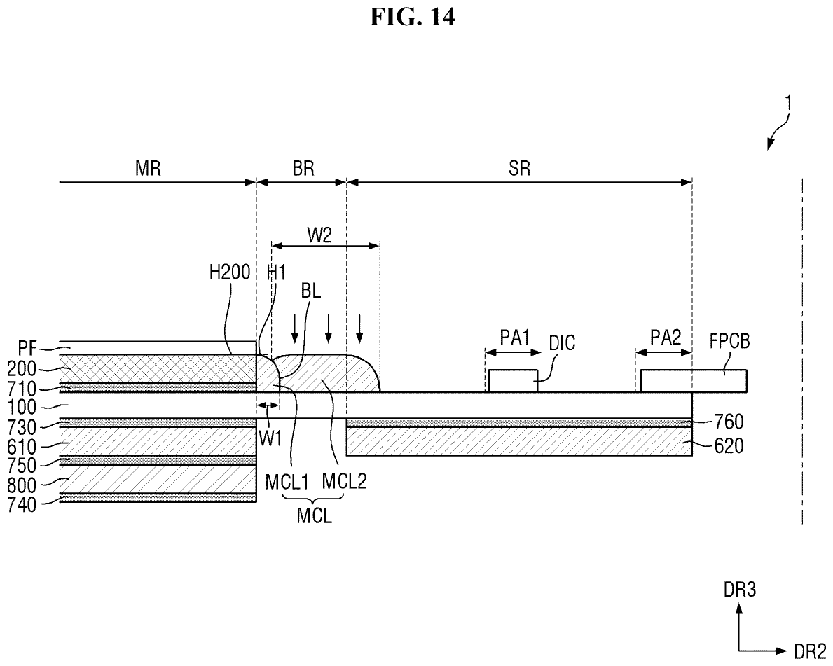

As shown in FIG. 13, the surface height H1 of the first covering layer MCL1 may be configured to be the same as the surface height H200 of the polarization layer 200, but the embodiments of this disclosure are not limited thereto. The first covering layer MCL1, once formed or applied, may be cured through thermal curing or ultraviolet curing, but the embodiments of this disclosure are not limited thereto. In some embodiments, the first covering layer MCL1 may be both applied and cured simultaneously, but the embodiments of this disclosure are not limited thereto. For example, the first covering layer MCL1 may include a material with a viscosity of approximately 700 cps to 900 cps, higher compared to the second covering layer MCL2 shown in FIG. 14, but the embodiments of this disclosure are not limited thereto.

Next, as shown in FIG. 11 and FIG. 14, the second covering layer MCL2 may be formed (indicated by arrows). The width W2 of the second covering layer MCL2 may be larger than the width W1 of the first covering layer MCL1, but the embodiments of this disclosure are not limited thereto. After curing, the modulus of the second covering layer MCL2 may be smaller than the modulus of the first covering layer MCL1. For example, the modulus may be the Young's Modulus. For example, the modulus of the second covering layer MCL2 may range from approximately 100 MPa to approximately 250 MPa, and the modulus of the first covering layer MCL1 may be less than approximately 100 MPa, but the embodiments of this disclosure are not limited thereto. The first covering layer MCL1 may prevent the second covering layer MCL2 from overflowing into the display area DA, for example, acting as a dam, and the second covering layer MCL2 may relieve the bending stress of the display panel 100 at the bending region BR, and therefore, the second covering layer MCL2 may be made of a more flexible material compared to the first covering layer MCL1, but the embodiments of this disclosure are not limited thereto.

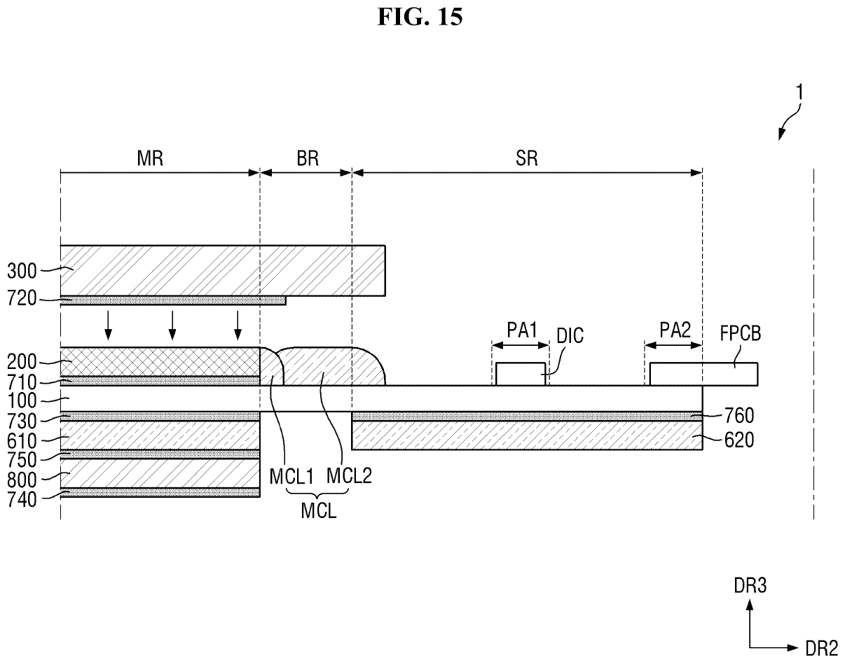

Furthermore, as shown in FIGS. 11 and 15, the protective film PF may be removed, and the cover layer 300 may be placed on the polarization layer 200 (as indicated by the arrows). The bottom surface of the cover layer 300 has the second bonding layer 720 attached, but the embodiments of this disclosure are not limited thereto.

In the display apparatus 1 according to an embodiment, by configuring the surface height H1 of the first covering layer MCL1 to be the same as the surface height H200 of the polarization layer 200, forming the first covering layer MCL1 as a dam, and forming the second covering layer MCL2, the interference between the second bonding layer 720 and the cover layers MCL1 and MCL2 during the bonding process of the cover layer 300 and the polarization layer 200 can be minimized. This helps to prevent external visibility issues caused by the second bonding layer 720 in advance. For example, when interference exists between the second bonding layer 720 and the cover layers MCL1 and MCL2 during the bonding process of the cover layer 300 to the polarization layer 200, unwanted air gaps may form between the second bonding layer 720 and the first covering layer MCL1, or between the second bonding layer 720 and the second covering layer MCL2, which could be visible from the outside. According to an embodiment, since the interference between the second bonding layer 720 and the covering layers MCL1 and MCL2 is prevented, external visibility issues can be improved. Additionally, since the interference between the second bonding layer 720 and the covering layers MCL1 and MCL2 is prevented, the occurrence of waviness in the second bonding layer 720 during the bending process of the display panel 100 can be reduced or improved.

Hereinafter, descriptions are provided of the display apparatus according to other embodiments. In the following embodiments, detailed explanations of the reference numerals or configurations already described with reference to FIGS. 1 to 15 will be omitted to avoid redundancy.

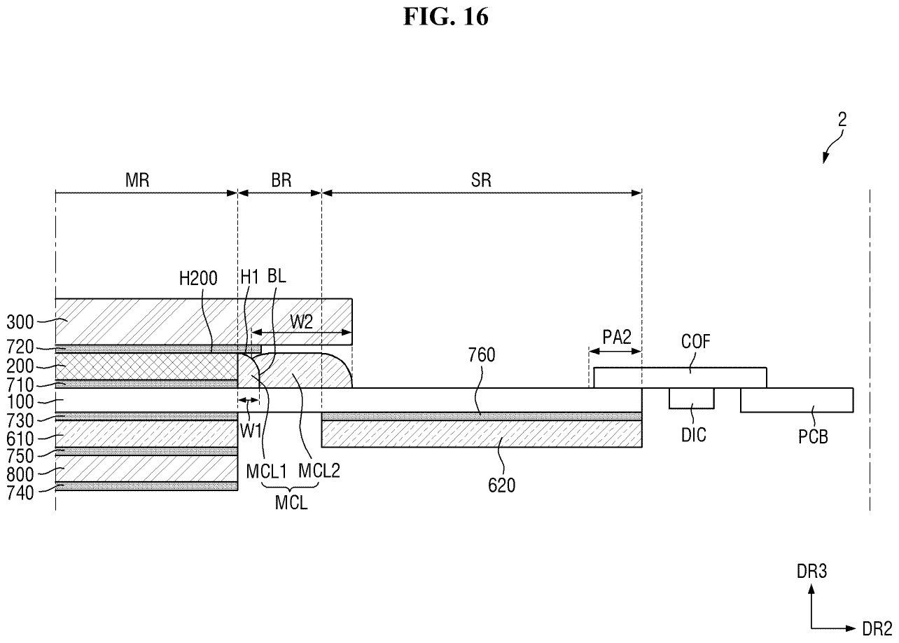

FIG. 16 is a cross-sectional view of a display device according to another embodiment.

Referring to FIG. 16, the display apparatus 2 according to this embodiment does not include the first pad area PA1, the second pad area PA2 has the printed circuit film COF attached, and the printed circuit board PCB may be attached to the end of the printed circuit film COF.

For example, the data driving unit DIC may be placed on the printed circuit film COF.

Since the other details are the same as those described with reference to FIGS. 11 to 15, detailed explanations thereof will be omitted.

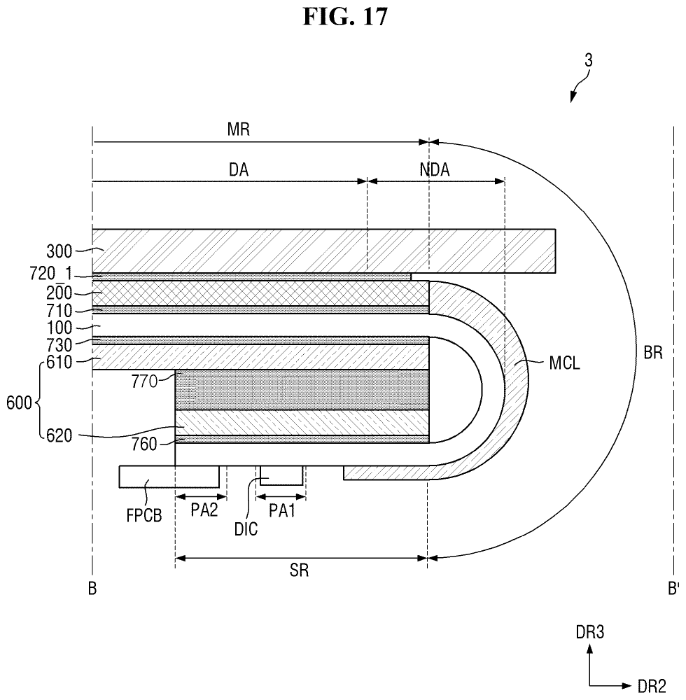

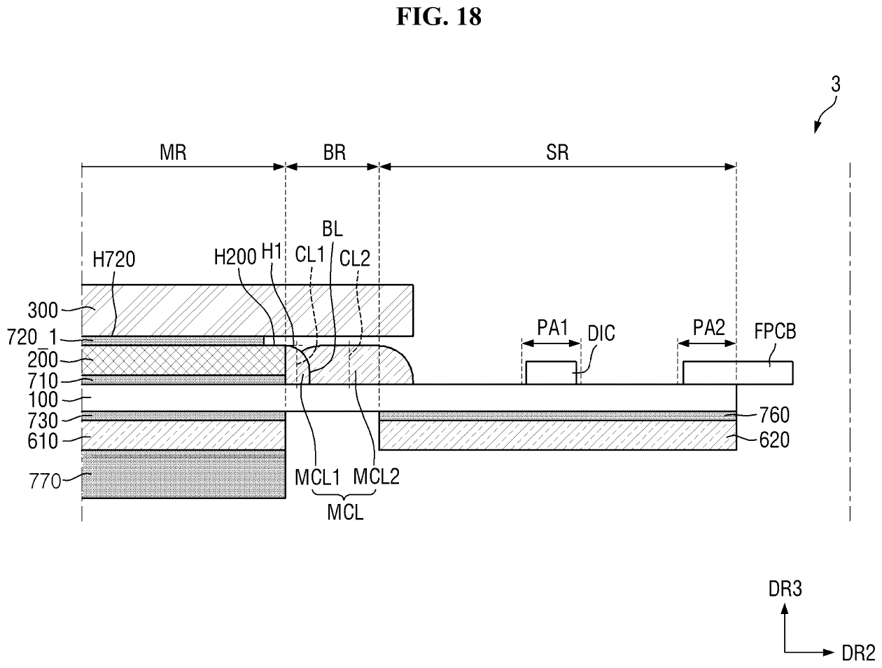

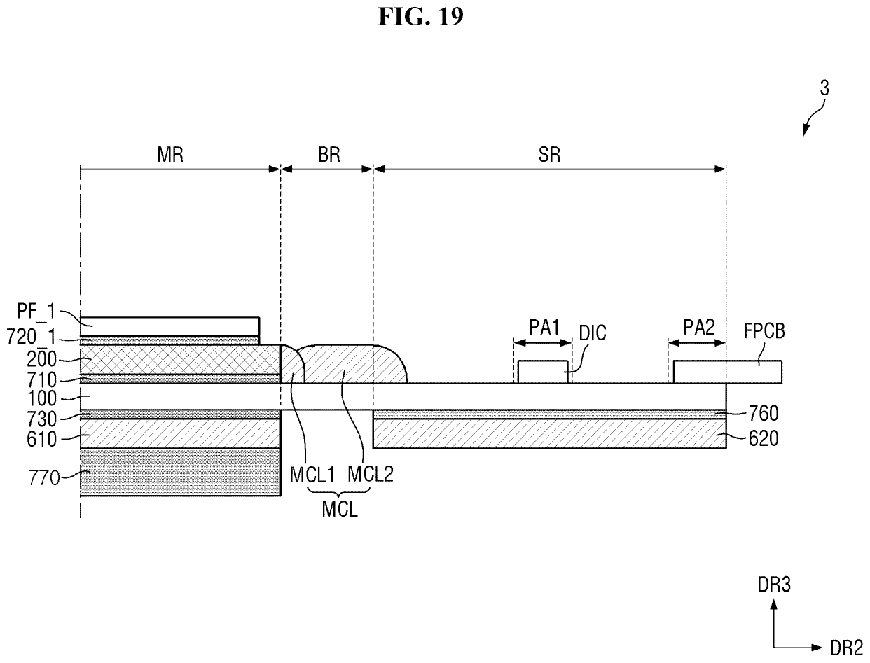

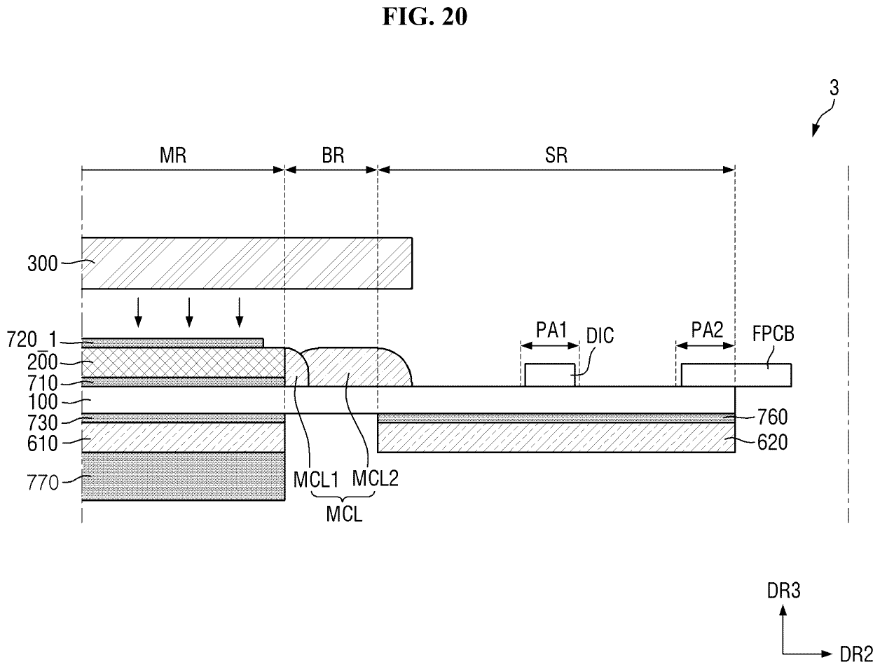

FIG. 17 is a cross-sectional view of a display device according to another embodiment. FIG. 18 is a cross-sectional view of a display device according to another embodiment. FIGS. 19 to 20 are cross-sectional views for explaining the manufacturing method of the display apparatus of FIG. 18.

Referring to FIGS. 17 to 20, the display apparatus 3 according to this embodiment omits the plate layer 800 from FIG. 7, and a seventh bonding layer 770 (or bending bonding layer) may be placed between the first backplate layer 610 and the second backplate layer 620. The first backplate layer 610 and the second backplate layer 620 can be bonded through the seventh bonding layer 770. The seventh bonding layer 770 may include at least one or more of the same material as the third bonding layer 730, the fourth bonding layer 740, the fifth bonding layer 750, and the sixth bonding layer 760, but the embodiments of this disclosure are not limited thereto.

In this embodiment, the end of the second bonding layer 7201 may be positioned farther from the bending region BR compared to the end of the polarization layer 200 (or it may be farther than the end of the polarization layer 200). For example, the end of the polarization layer 200 may be located closer to the bending region BR compared to the end of the second bonding layer 7201 (or closer than the end of the polarization layer 200). The end of the second bonding layer 720_1 may be recessed into the main region MR compared to the end of the polarization layer 200 (or farther than the end of the polarization layer 200).

Referring to FIG. 18, the covering layer MCL of the display apparatus 3 according to this embodiment may include the first covering layer MCL1 and the second covering layer MCL2. The second covering layer MCL2 may be in contact with the first covering layer MCL1. The first covering layer MCL1 may be in contact with or in direct contact with the side of the polarization layer 200 and the first bonding layer 710. The first covering layer MCL1 may be spaced apart from the second bonding layer 720_1. The end of the second bonding layer 7201 may be recessed into the main region MR compared to the end of the polarization layer 200 (or farther than the end of the polarization layer 200). The surface height H1 of the first covering layer MCL1 may be lower than the surface height H720 of the second bonding layer 720_1 and higher than the surface height H200 of the polarization layer 200, but the embodiments of this disclosure are not limited thereto.

The first covering layer MCL1 and the second covering layer MCL2 may include different materials. For example, the first covering layer MCL1 and the second covering layer MCL2 may be formed in different processes, but the embodiments of this disclosure are not limited thereto.

The first covering layer MCL1 and the second covering layer MCL2 are formed in different processes, with the first covering layer MCL1 being formed first and then the second covering layer MCL2, so a boundary BL may exist between the first and second covering layers as shown in FIG. 18. Furthermore, the first covering layer MCL1 and the second covering layer MCL2 may each have a reduced thickness at the boundary BL therebetween compared to the central parts CL1 and CL2 of the covering layers MCL1 and MCL2. For example, the first covering layer MCL1 and the second covering layer MCL2 may each have a concave shape (or recessed shape) downward at the boundary therebetween.

Hereinafter, the manufacturing process of the first covering layer MCL1 and the second covering layer MCL2 is described.

As shown in FIGS. 18 and 19, a protective film PF_1 may be disposed on the second bonding layer 720_1. Before forming or applying the first covering layer MCL1, as shown in FIG. 13, plasma treatment may be applied to the side surface of the polarization layer 200 to ensure good contact between the first covering layer MCL1 and the polarization layer 200, but the embodiments of this disclosure are not limited thereto. Afterward, the first covering layer MCL1 may be formed on the side surface of the polarization layer 200 and the side surface of the first bonding layer 710. The first covering layer MCL1 may be formed in the bending region BR and applied or formed to contact the side surface of the polarization layer 200 and the side surface of the first bonding layer 710, and the formed or applied first covering layer MCL1 may be cured through heat curing or ultraviolet curing, but the embodiments of this disclosure are not limited thereto. In some embodiments, the first covering layer MCL1 may be both applied and cured simultaneously, but the embodiments of this disclosure are not limited thereto. For example, the first covering layer MCL1 may include a material with a viscosity of approximately 700 cps to 900 cps, higher compared to the second covering layer MCL2, but the embodiments of this disclosure are not limited thereto. Subsequently, the second covering layer MCL2 is formed. The width of the second covering layer MCL2 may be greater than that of the first covering layer MCL1, but the embodiments of this disclosure are not limited thereto. After curing, the modulus of the second covering layer MCL2 may be smaller than the modulus of the first covering layer MCL1. For example, the modulus may be the Young's Modulus. For example, the modulus of the second cover layer MCL2 may range from approximately 100 MPa to approximately 250 MPa, and the modulus of the first cover layer MCL1 may be less than approximately 100 MPa, but the embodiments of this disclosure are not limited thereto. The first covering layer MCL1 may prevent the second covering layer MCL2 from overflowing into the display area DA, for example, acting as a dam, and the second covering layer MCL2 may relieve the bending stress of the display panel 100 at the bending region BR, so the second covering layer MCL2 may be made of a more flexible material compared to the first covering layer MCL1, but the embodiments of this disclosure are not limited thereto.

Next, as shown in FIGS. 18 and 20, the protective film PF_1 (see FIG. 19) may be removed, and the cover layer 300 may be disposed on the second bonding layer 7201 (as indicated by the arrow).

In the display apparatus 3 according to an embodiment, the end of the second bonding layer 720_1 is recessed inward compared to the end of the polarization layer 200 (or farther from the end of the polarization layer 200), and after forming the first covering layer MCL1, the second covering layer MCL2 is formed, such that the second bonding layer 7201 and the first covering layer MCL1 are spaced apart, minimizing physical interference. This can improve the attachment defect between the cover layer 300 and the second bonding layer 720_1 during the attachment process of the cover layer 300. For example, when the second covering layer MCL2 overflows to the upper surface of the protective film PF_1, and the protective film PF_1 is peeled off and the cover layer 300 is attached to the second bonding layer 720_1, the second covering layer MCL2 and the cover layer 300 may interfere with each other. Since the attachment defect between the cover layer 300 and the second bonding layer 720_1 is improved, it is possible to prevent the generation of air bubbles between the cover layer 300 and the polarization layer 200, and/or between the cover layer 300 and the second bonding layer 7201, thereby improving external visibility defects. Furthermore, since air bubbles can be prevented from forming between the cover layer 300 and the polarization layer 200, and/or between the cover layer 300 and the second bonding layer 720_1, defects in the display apparatus caused by air bubbles can be reduced, and the lifespan of the display apparatus can be improved.

Since the other details are the same as those described with reference to FIGS. 1 to 11, detailed explanations thereof will be omitted.

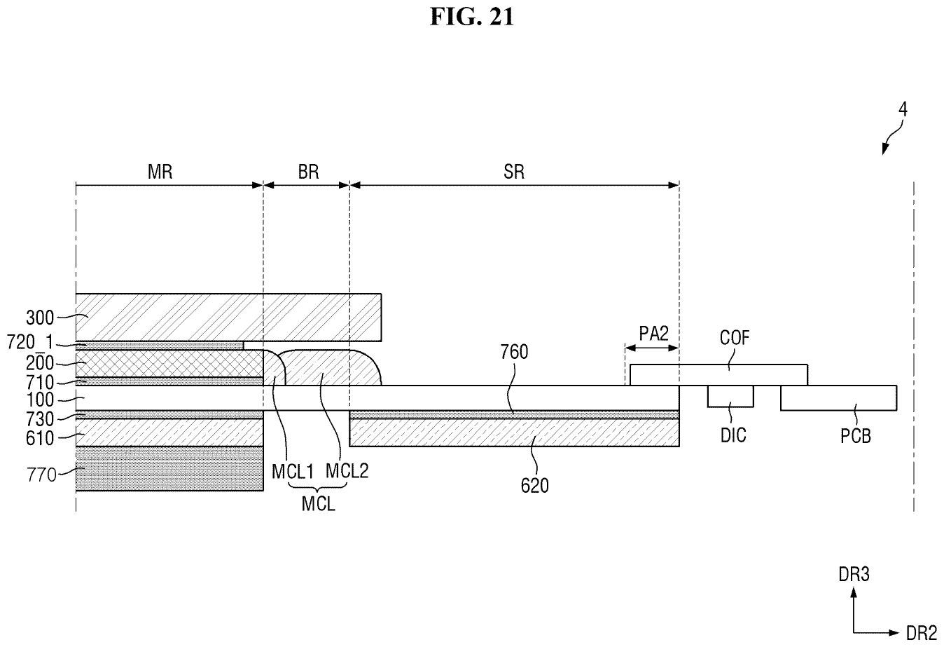

FIG. 21 is a cross-sectional view of a display device according to another embodiment.

Referring to FIG. 21, the display apparatus 4 according to this embodiment does not include the first pad area PA1, the second pad area PA2 has the printed circuit film COF attached, and the printed circuit board PCB may be attached to the end of the printed circuit film COF. Since the other details are the same as those of the display apparatus 3 described with reference to FIG. 18, detailed explanations thereof will be omitted.

The display apparatus according to various embodiments of this disclosure may be described as follows.

A display apparatus according to various embodiments of this disclosure may include a display panel, a main region, a sub-region, a bending region between the main region and the sub-region, a polarization layer disposed in the main region, a cover layer on the polarization layer, a bonding layer between the polarization layer and the cover layer, and a covering layer disposed in the bending region. The bonding layer may have an end that is farther from the bending region than an end of the polarization layer, and the covering layer may be spaced apart from the bonding layer.

According to various embodiments of this disclosure, the covering layer may be in direct contact with a side surface of the polarization layer.

According to various embodiments of this disclosure, the covering layer may include a first covering layer in contact with a side surface of the polarization layer; and a second covering layer in contact with the first covering layer.

According to various embodiments of this disclosure, the second covering layer may have a surface height higher than a surface height of the first covering layer.

The display apparatus according to various embodiments of this disclosure may further include a first backplate layer beneath the main region, and a second backplate layer beneath the sub-region.

The display apparatus according to various embodiments of this disclosure may further include a bonding layer between the first backplate layer and the second backplate layer.

According to various embodiments of this disclosure, the first covering layer and the second covering layer may include different materials. According to various embodiments of this disclosure, the first covering layer may have a modulus greater than a modulus of the second covering layer.

According to various embodiments of this disclosure, the first covering layer and the second covering layer may each have a thickness thinner at a boundary therebetween than at respective central portions thereof.

The display apparatus according to various embodiments of this disclosure may further include a first transistor on the substrate in the main region, and a second transistor between the first transistor and a touch layer. According to various embodiments of this disclosure, the source electrode of the first transistor and the source electrode of the second transistor may be in the same layer.

The display apparatus according to various embodiments of this disclosure may further include a light-emitting layer on the second transistor, a first protective layer between the second transistor and the light-emitting layer, a connection electrode on the first protective layer, and a second protective layer between the connection electrode and the touch layer. According to various embodiments of this disclosure, the connection electrode may electrically connect the anode electrode of the light-emitting layer and the source electrode or drain electrode of the second transistor.

A display apparatus according to various embodiments of this disclosure may include a display panel, a main region, a sub-region, a bending region between the main region and the sub-region, a polarization layer disposed in the main region, a cover layer on the polarization layer, a bonding layer between the polarization layer and the cover layer, and a covering layer disposed in the bending region. According to various embodiments of this disclosure, the bonding layer may have an end protruding further toward the bending region compared to an end of the polarization layer. According to various embodiments of this disclosure, the covering layer may include a first covering layer in contact with the side surface of the polarization layer, and a second covering layer located outside the first covering layer and in contact with the first covering layer. According to various embodiments of this disclosure, the first covering layer may have a surface height equal to the surface height of the polarization layer.

According to various embodiments of this disclosure, the second covering layer may have a surface height higher than a surface height of the first covering layer.

The display apparatus according to various embodiments of this disclosure may further include a first backplate layer beneath the main region, and a second backplate layer beneath the sub-region.

The display apparatus according to various embodiments of this disclosure may further include a plate layer between the first backplate layer and the second backplate layer.

According to various embodiments of this disclosure, the first covering layer and the second covering layer may include different materials.

According to various embodiments of this disclosure, the first covering layer and the second covering layer may each have a thickness thinner at a boundary therebetween than at respective central portions thereof.

The display apparatus according to the embodiments is advantageous in preventing the cover layer from encroaching into the display area by incorporating a first and second covering layer into the overall cover structure. This prevention facilitates the expansion of the display area, allowing for a reduction in the bezel area (or non-display area). As a result, a display apparatus with a narrow bezel can be implemented.

The display apparatus according to the embodiments is advantageous in preventing external visibility defects caused by the bonding layer by minimizing interference between the bonding layer and the cover layer, achieved by equalizing the surface heights of the first cover layer and the polarization layer. This minimization of interference between the bonding layer and the cover layer can help reduce the occurrence of bending (waviness) in the bonding layer during the bonding process of the display panel.

The display apparatus according to the embodiments is advantageous in minimizing physical interference between the bonding layer and the first cover layer by configuring them to be spaced apart. This minimization of physical interference between the bonding layer and the first cover layer can help reduce attachment defects in the process of attaching the cover layer to the bonding layer. The reduction of attachment defects of the cover layer helps prevent bubble formation between the cover layer and the polarization layer and/or between the cover layer and the bonding layer, thereby improving visibility defects in the display apparatus.

The display apparatus according to the embodiments is advantageous in reducing defects caused by bubbles forming between the bonding layer and the cover layer and/or between the cover layer and the polarization layer by configuring a first and second cover layer, thereby enhancing the lifespan of the display apparatus.

The advantages of this disclosure are not limited to the aforesaid, and other advantages not described herein may be clearly understood by those skilled in the art from the disclosure.

Although embodiments of this invention have been described above with reference to the accompanying drawings, it will be understood that the technical configuration of the this invention described above can be implemented in other specific forms by those skilled in the art without changing the technical concept or essential features of the present invention. Therefore, it should be understood that the embodiments described above are examples and not limited in all respects. Furthermore, the scope of the present invention is defined by the claims set forth below and their equivalents, rather than the detailed description above. In addition, it should be understood that all modifications or variations derived from the meaning and scope of the claims and their equivalent concept are included within the scope of this invention.

What is claimed is:

1. A display apparatus, comprising:
a display panel;
a main region, a sub-region, and a bending region between the main region and the sub-region;
a polarization layer disposed in the main region;
a cover layer on the polarization layer;
a bonding layer between the polarization layer and the cover layer; and
a covering layer disposed in the bending region,
wherein the bonding layer has an end that is farther from the bending region than an end of the polarization layer, and the covering layer is spaced apart from the bonding layer.

2. The display apparatus of claim 1, wherein the covering layer is in direct contact with a side surface of the polarization layer.

3. The display apparatus of claim 2, wherein the covering layer comprises:
a first covering layer in contact with a side surface of the polarization layer; and
a second covering layer in contact with the first covering layer.

4. The display apparatus of claim 3, wherein the second covering layer has a surface height higher than a surface height of the first covering layer.

5. The display apparatus of claim 1, further comprising:
a first backplate layer beneath the main region; and
a second backplate layer beneath the sub-region.

6. The display apparatus of claim 5, further comprising another bonding layer between the first backplate layer and the second backplate layer.

7. The display apparatus of claim 3, wherein the first covering layer and the second covering layer include different materials, and the first covering layer has a modulus greater than a modulus of the second covering layer.

8. The display apparatus of claim 3, wherein the first covering layer and the second covering layer each have a thickness thinner at a boundary therebetween than at respective central portions thereof.

9. The display apparatus of claim 1, further comprising:
a first transistor and a second transistor spaced apart from the first transistor, the first and second transistors being disposed in the main region,
wherein a source electrode of the first transistor and a source electrode of the second transistor are in a same layer.

10. The display apparatus of claim 9, further comprising:
a light-emitting layer on the second transistor;
a first protective layer between the second transistor and the light-emitting layer;
a connection electrode on the first protective layer; and
a second protective layer on the connection electrode,
wherein the connection electrode electrically connects an anode electrode of the light-emitting layer and the source electrode or a drain electrode of the second transistor.

11. The display apparatus of claim 3, wherein the first covering layer includes a material with a viscosity higher than a viscosity of a material included in the second covering layer.

12. The display apparatus of claim 3, wherein a width of the second covering layer is greater than a width of the first covering layer.

13. A display apparatus, comprising:
a display panel;
a main region, a sub-region, and a bending region between the main region and the sub-region;
a polarization layer disposed in the main region;
a cover layer on the polarization layer;
a bonding layer between the polarization layer and the cover layer; and
a covering layer disposed in the bending region,
wherein the bonding layer has an end protruding further toward the bending region compared to an end of the polarization layer,
wherein the covering layer comprises a first covering layer in contact with a side surface of the polarization layer, and a second covering layer located outside the first covering layer and in contact with the first covering layer, and
wherein the first covering layer has a surface height equal to a surface height of the polarization layer.

14. The display apparatus of claim 13, wherein the second covering layer has a surface height higher than the surface height of the first covering layer.

15. The display apparatus of claim 13, further comprising:
a first backplate layer beneath the main region; and
a second backplate layer beneath the sub-region.

16. The display apparatus of claim 15, further comprising:
a plate layer between the first backplate layer and the second backplate layer.

17. The display apparatus of claim 13, wherein the first covering layer and the second covering layer include different materials.

18. The display apparatus of claim 13, wherein the first covering layer and the second covering layer each have a thickness thinner at a boundary therebetween than at respective central portions thereof.

19. The display apparatus of claim 13, wherein the second covering layer is made of a more flexible material compared to the first covering layer.
